(19) United States
(12) Patent Application Publication
(10) Pub. No.: US 2026/0082750 A1
(43) Pub. Date: Mar. 19, 2026

(54) DISPLAY APPARATUS

(71) Applicant: LG Display Co., Ltd., Seoul (KR)

(72) Inventor: Junwon LEE, Gyeongsan-si (KR)

(73) Assignee: LG Display Co., Ltd., Seoul (KR)

(21) Appl. No.: 19/284,466

(22) Filed: Jul. 29, 2025

(30) Foreign Application Priority Data
Sep. 13, 2024 (KR) 10-2024-0125778

(51) Int. Cl. H10H 29/49; H01L 25/16; H10H 29/37; H10H 29/41

(52) U.S. Cl. CPC H10H 29/49; H10H 29/37; H10H 29/41; H10W 90/00

(57) ABSTRACT

A display apparatus includes a substrate including an active area and a non-active area, a plurality of insulating layers on the substrate, and a plurality of light emitting elements positioned in the active area on the insulating layers. A plurality of wiring lines is disposed in the non-active area on different insulating layers and at least partially overlaps each other. A plurality of pad electrodes is also disposed in the non-active area on the insulating layers and electrically connected to the wiring lines. One ends of the wiring lines are electrically connected to the same pad electrode, while the other ends are electrically connected to different pad electrodes. This configuration allows for detection of discontinuities in individual wiring lines and may improve the crack detectability in the display apparatus.

### CROSS-REFERENCE TO RELATED APPLICATIONS

This application claims the benefit and priority to Korean Patent Application No. 10-2024-0125778 filed on Sep. 13, 2024, in the Korean Intellectual Property Office, the entire disclosure of which is incorporated herein by reference for all purposes, as if fully set forth herein.

### BACKGROUND

### Technical Field

The present disclosure relates to a display apparatus, and particularly to, for example, without limitation, a display apparatus with an improved crack detectability.

### Description of the Related Art

Display apparatuses are being applied to various electronic devices, such as TVs, mobile phones, laptops, and tablets.

As display apparatuses, there are an organic light emitting display (OLED) apparatus which is a self-emitting device and a liquid crystal display (LCD) apparatus which requires a separate light source.

Recently, a display apparatus including a light emitting diode (LED) is attracting attention as a next generation display apparatus. The light emitting diode is formed of an inorganic material, rather than an organic material so that lighting speed is faster, a luminous efficiency is excellent, and an image with a higher luminance may be displayed, as compared with the liquid crystal display or the organic light emitting display apparatus.

The description provided in the background section should not be assumed to be prior art merely because it is mentioned in or associated with the background section. The background section may include information that describes one or more aspects of the subject technology.

### BRIEF SUMMARY

Various embodiments of the disclosed display apparatus include a crack detection system configured to enhance structural reliability while maintaining display performance. A plurality of crack detection lines is arranged in the non-active region of the display substrate across multiple insulating layers. These crack detection lines are configured to at least partially overlap one another and are routed such that one end of each line connects to a common signal input pad while the other ends connect to different signal output pads. This arrangement allows individual monitoring of each line, enabling accurate identification of line breaks or discontinuities caused by cracks.

The detection lines are positioned outside the image display region, avoiding interference with pixel-driving circuits and light-emitting components. The architecture is particularly suitable for displays with flexible or bendable substrates, as the crack detection lines are routed through designated substrate areas, including a bending region. The use of conductive materials with high ductility and multi-layered configurations helps maintain line integrity under mechanical stress, contributing to extended device lifespan and reduced risk of contamination through cracks.

This structure provides improved monitoring resolution and reliability by allowing separate detection of signal loss along each line. It supports efficient diagnosis of structural failure while maintaining compatibility with advanced display configurations, such as micro light emitting diode arrays. The approach enhances durability and operational stability under physical stress, making it well-suited for high-performance electronic displays.

For example, an aspect of the present disclosure is to provide a display apparatus with an improved crack detectability.

Another aspect of the present disclosure is to provide a display apparatus which easily detects a crack to minimize or reduce a potential defect due to the crack to improve the lifespan of the display apparatus, thereby being driven at a low power in terms of reduction of power consumption.

Yet another aspect of the present disclosure is to provide a display apparatus with an improved reliability by minimizing or reducing impurity permeation due to the crack.

Aspects of the present disclosure are not limited to the above-mentioned aspects, and other aspects, which are not mentioned above, can be clearly understood by those skilled in the art from the following descriptions.

Additional features and aspects of the disclosure are set forth in part in the description that follows and in part will become apparent from the description or may be learned by practice of the inventive concepts provided herein. Other features and aspects of the inventive concepts may be realized and attained by the structures pointed out in the present disclosure, or derivable therefrom, and the claims hereof as well as the appended drawings.

To achieve these and other aspects of the inventive concepts, as embodied and broadly described herein, a display apparatus includes a substrate including an active area and a non-active area adjacent to the active area, a plurality of insulating layers disposed on the substrate, a plurality of banks disposed on the plurality of insulating layers in the active area, a plurality of light emitting elements disposed on the banks, a plurality of wiring lines which is disposed so as to surround the active area on different insulating layers, among the plurality of insulating layers, in the non-active area and at least partially overlap each other, and a plurality of pad electrodes which is disposed on the plurality of insulating layers in the non-active area and is electrically connected to the plurality of wiring lines. One ends of the plurality of wiring lines are electrically connected to the same pad electrode, among the plurality of pad electrodes and the other ends of the plurality of wiring lines are electrically connected to different pad electrodes, among the plurality of pad electrodes.

According to an aspect of the present disclosure, a display apparatus includes a substrate including an active area and a non-active area adjacent to the active area, a plurality of insulating layers disposed on the substrate, a plurality of banks disposed on the plurality of insulating layers in the active area, a plurality of micro light emitting elements disposed on the banks, a plurality of wiring lines which is disposed so as to surround the active area on different insulating layers, among the plurality of insulating layers, in the non-active area and at least partially overlaps each other and a plurality of pad electrodes which is disposed on the plurality of insulating layers in the non-active area and is electrically connected to the plurality of wiring lines. One ends of each of the plurality of wiring lines are electrically connected to the same pad electrode, among the plurality of pad electrodes and the other ends of each of the plurality of wiring lines are electrically connected to different pad electrodes, among the plurality of pad electrodes.

According to another aspect of the present disclosure, a display apparatus includes a substrate which includes an active area, a first non-active area adjacent to the active area, a bending area extending from the first non-active area, and a second non-active area extending from the bending area, a plurality of insulating layers disposed on the substrate, a plurality of banks disposed on the plurality of insulating layers in the active area, a plurality of light emitting elements disposed on the banks, a plurality of crack detection lines which is disposed so as to surround the active area on different insulating layers, among the plurality of insulating layers, in the first non-active area and at least partially overlap each other, and a plurality of pad electrodes which is disposed on the plurality of insulating layers in the second non-active area and includes a signal transmission pad electrode and a plurality of signal reception pad electrodes which are electrically connected to the plurality of wiring lines. Accordingly, the crack detectability may be improved.

Other detailed matters of the exemplary embodiments are included in the detailed description and drawings.

According to the present disclosure, a plurality of crack detection lines are disposed to improve the crack detectability.

According to the present disclosure, the plurality of crack detection lines is connected to different signal reception pads to read a signal for every crack detection line, thereby easily detecting whether there is a crack for every crack detection line.

According to the present disclosure, a potential defect due to the crack is minimized or reduced and the lifespan of the display apparatus is improved to be driven at a low power in terms of reduction of a power consumption.

According to the present disclosure, the crack detectability is improved to minimize or reduce the impurity permeation by the crack, thereby improving the reliability of the display apparatus.

The effects according to the present disclosure are not limited to the contents exemplified above, and more various effects are included in the present specification.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The accompanying drawings, that may be included to provide a further understanding of the disclosure and may be incorporated in and constitute a part of the disclosure, illustrate embodiments of the disclosure and together with the description serve to explain various principles of the disclosure.

The above and other aspects, features and other advantages of the present disclosure will be more clearly understood from the following detailed description taken in conjunction with the accompanying drawings, in which:

FIG. 1 is an exploded perspective view of a display apparatus according to an exemplary embodiment of the present disclosure;

FIG. 2A is a plan view of a display apparatus according to an exemplary embodiment of the present disclosure;

FIG. 2B is an enlarged view of a display apparatus according to an exemplary embodiment of the present disclosure;

FIGS. 3A to 3E are plan views of a display apparatus according to an exemplary embodiment of the present disclosure;

FIG. 4 is a view illustrating a circuit structure according to an exemplary embodiment of the present disclosure;

FIG. 5 is a plan view of a display apparatus according to an exemplary embodiment of the present disclosure;

FIG. 6 is a plan view of a display apparatus according to an exemplary embodiment of the present disclosure;

FIG. 7 is a plan view of a display apparatus according to an exemplary embodiment of the present disclosure;

FIG. 8 is a cross-sectional view taken along VIII-VIII′ of FIG. 2B;

FIG. 9 is a cross-sectional view of a display apparatus according to an exemplary embodiment of the present disclosure;

FIG. 10 is a cross-sectional view taken along X-X′ of FIG. 2A;

FIG. 11A is a cross-sectional view taken along A-A′ of FIG. 2A;

FIG. 11B is a cross-sectional view taken along B-B′ of FIG. 2A;

FIG. 11C is a cross-sectional view taken along C-C′ of FIG. 2A;

FIG. 11D is a cross-sectional view taken along D-D′ of FIG. 2A;

FIG. 11E is a cross-sectional view taken along E-E′ of FIG. 2A; and

FIGS. 12 to 15 are views illustrating devices to which a display apparatus according to exemplary embodiments of the present disclosure is applied.

Throughout the drawings and the detailed description, unless otherwise described, the same drawing reference numerals should be understood to refer to the same elements, features, and structures.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure and a method of achieving the advantages and features will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure. Any implementation described herein as an “example” is not necessarily to be construed as preferred or advantageous over other implementations.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with a more limiting term such as “only”. An element described in the singular form is intended to include a plurality of elements, and vice versa, unless the context clearly indicates otherwise.

In construing an element, the element is construed as including an ordinary error range or tolerance range although there is no explicit description of such an error or tolerance range.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

When explaining temporal relationships, terms such as “after,” “following,” “subsequent to,” “next to,” or “before,” etc., may include non-consecutive cases unless a more limiting term, such as “immediately” or “directly” is used.

Terms such as “first,” “second,” “A”, “B”, “(a)”, “(b),” etc., are used to describe various components, but the essence, sequence, order, or number of these components are not limited by these terms. These terms are merely used to distinguish one component from another. For example, a first component could be termed a second component, and, similarly, a second component could be termed a first component, without departing from the scope of the present disclosure.

In describing the components of the present disclosure, terms such as first, second, A, B, (a), or (b) may be used. These terms are only intended to distinguish that one component from other components, and the nature, order, sequence, or number of the respective component is not limited by these terms.

When a component is described as being “connected,” “coupled,” “joined,” or “attached” to another component, it should be understood that the component may be directly connected, coupled, joined, or attached to the other component, but unless explicitly specified otherwise, it may also be indirectly connected, coupled, joined, or attached with another component intervening between each component.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When a component or layer is described as being “in contact with” or “overlapping” another component or layer, the component or layer may directly contact or overlap the other component or layer, but unless explicitly specified otherwise, it should be understood that it may also indirectly contact or overlap with another component intervening between each component.

The term “at least one” should be understood to include all combinations of one or more of the associated components. For example, “at least one of first, second, and third components” means not only the first, second, or third component, but also includes all combinations of two or more components from among the first, second, and third components.

The terms “first direction”, “second direction”, “third direction”, “row direction”, “column direction”, “X-axis direction”, “Y-axis direction”, and “Z-axis direction” should not be interpreted solely as geometric relationships perpendicular to each other, but may indicate broader directionality within the range where the configuration of the present disclosure can function.

The features of various embodiments in the present disclosure may be partially or wholly combined or associated with each other, various technical interlocking and operations are possible, and each embodiment may be implemented independently of each other or may be implemented together in an associated relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, a display apparatus according to various example embodiments of the present disclosure will be described in detail with reference to accompanying drawings. Further, all the components of each display apparatus according to all embodiments of the present disclosure are operatively coupled and configured.

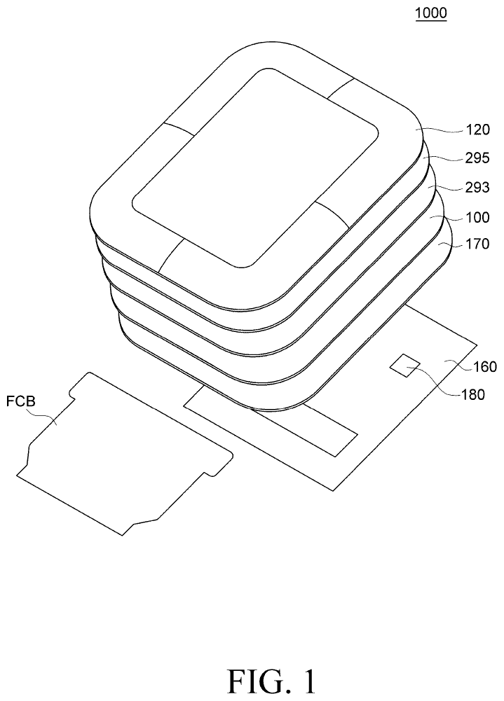

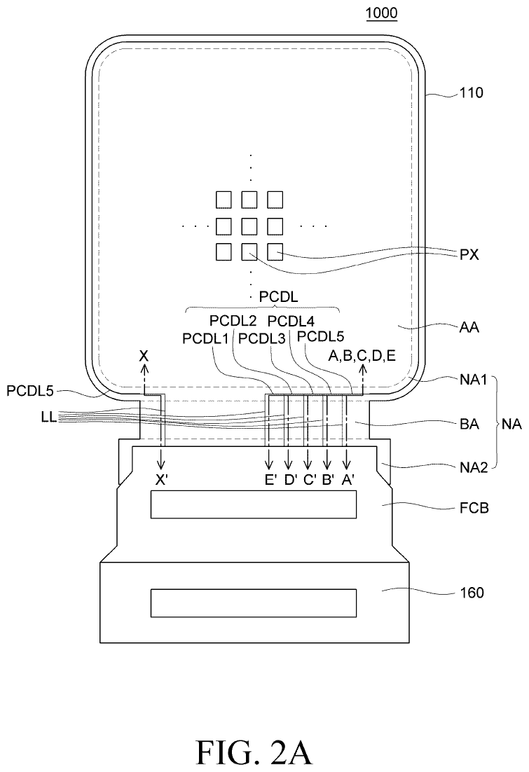

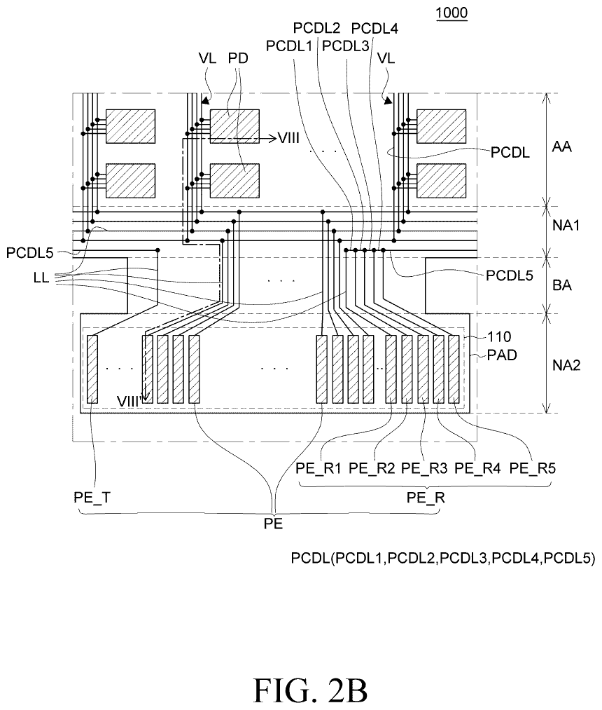

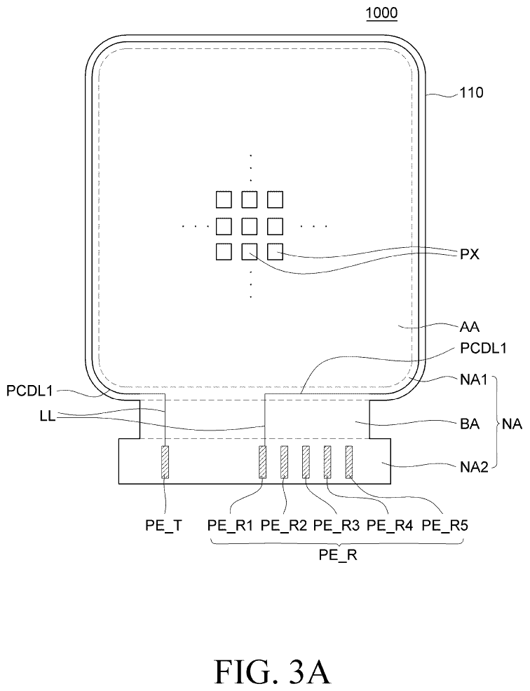

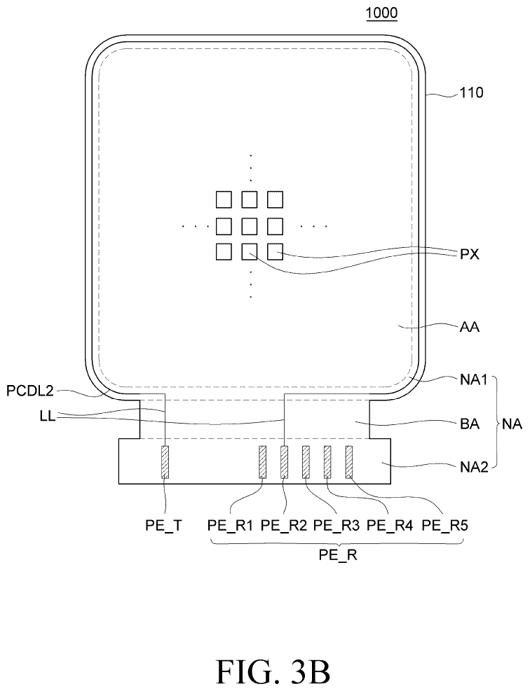

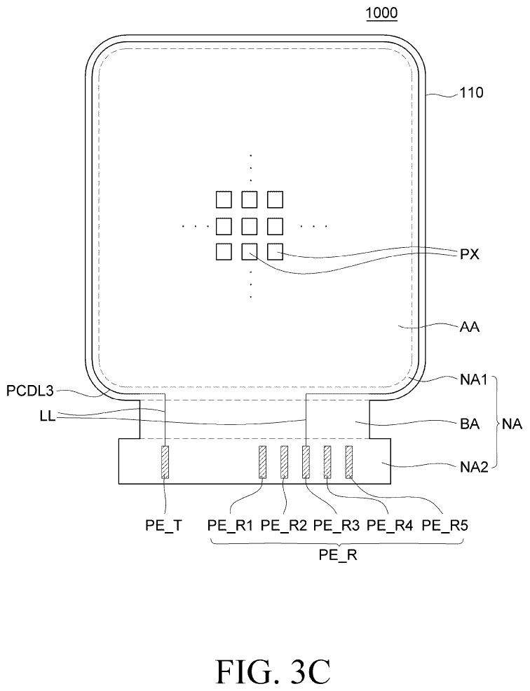

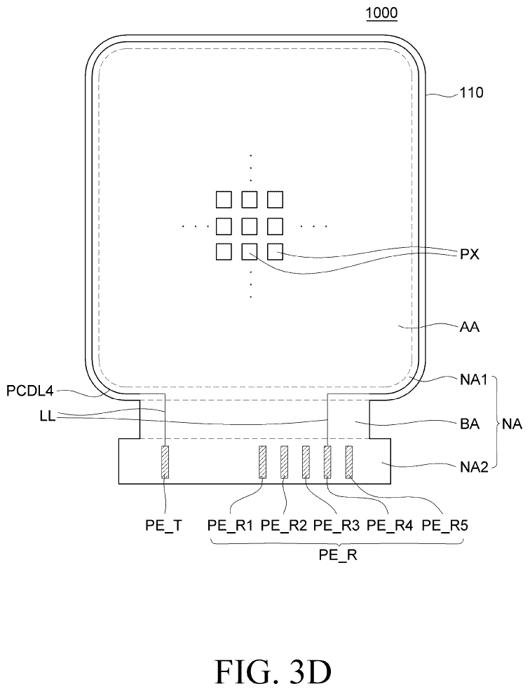

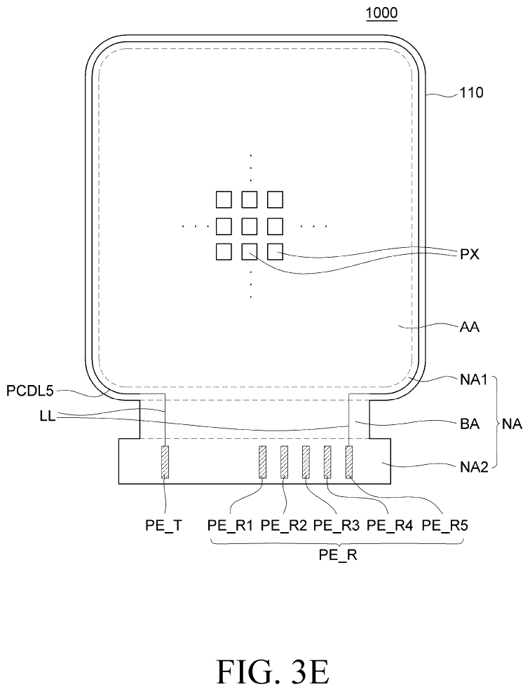

FIG. 1 is a perspective view illustrating a display apparatus according to an exemplary embodiment of the present disclosure. FIG. 2A is a plan view of a display apparatus according to an exemplary embodiment of the present disclosure. FIG. 2B is an enlarged view of a display apparatus according to an exemplary embodiment of the present disclosure. FIGS. 3A to 3E are plan views of a display apparatus according to an exemplary embodiment of the present disclosure. For the convenience of description, in FIG. 3A, only a first crack detection line PCDL1, among the plurality of crack detection lines PCDL is illustrated and in FIG. 3B, only a second crack detection line PCDL2, among the plurality of crack detection lines PCDL is illustrated. Further, in FIG. 3C, only a third crack detection line PCDL3, among the plurality of crack detection lines PCDL is illustrated and in FIG. 3D, only a fourth crack detection line PCDL4, among the plurality of crack detection lines PCDL is illustrated. In FIG. 3E, only a fifth crack detection line PCDL5, among the plurality of crack detection lines PCDL is illustrated.

Referring to FIGS. 1 to 3E, a display apparatus 1000 according to an exemplary embodiment of the present disclosure may include one or more of a display panel 100, a polarization layer 293, an adhesive layer 295, a cover member 120, a support substrate 170, a flexible circuit board FCB, and a printed circuit board 160. However, the present disclosure is not limited thereto, and more or less components may be included in the display apparatus of the present disclosure. For example, various other function layers such as a diffusion layer, a reflective layer may also be disposed on the display panel 100.

For example, the display panel 100 of the display apparatus 1000 may include a substrate 110. The substrate 110 may be a member which supports other components of the display apparatus 1000. The substrate 110 may be formed of an insulating material. For example, the substrate 110 may be formed of glass or resin. Further, the substrate 110 may also be formed of a material having flexibility. For example, the substrate 110 may be formed of a plastic material having flexibility, such as any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC), polyvinyl alcohol (PVA), polyimide (PI), and polystyrene (PS), but the exemplary embodiments of the present disclosure are not limited thereto.

The display panel 100 may implement information, videos, and/or images which are provided to users. For example, the display panel 100 may include an active area AA and a non-active area NA adjacent to the active area AA. For example, the substrate 110 may include an active area AA and a non-active area NA. However, the active area AA and the non-active area NA are not mentioned to be limited to the substrate 110, but may be mentioned for the entire display apparatus 1000.

The active area AA may be an area where images are displayed. The active area AA may include a plurality of pixels PX. Each of the plurality of pixels PX may include a plurality of sub pixels. A plurality of light emitting elements may be disposed in the plurality of sub pixels, respectively. The plurality of light emitting elements may be configured in different manners depending on the type of the display apparatus 1000. For example, when the display apparatus 1000 is an inorganic light emitting display apparatus, the light emitting element may be an inorganic-based light emitting device, such as a light emitting diode (LED), a micro light emitting diode (micro LED), or a mini light emitting diode (mini LED), but the exemplary embodiments of the present disclosure are not limited thereto. Hereinafter, the description will be made by assuming that the light emitting element of the display apparatus 1000 according to the exemplary embodiment of the present disclosure is a micro LED, but the exemplary embodiments of the present disclosure are not limited thereto.

The non-active area NA may be an area where no image is displayed. In the non-active area NA, various wiring lines and circuits for driving the plurality of pixels PX of the active area AA may be disposed. For example, in the non-active area NA, various wiring lines and driving circuits may be mounted and a pad unit PAD to which an integrated circuit and a printed circuit are connected may be disposed, but the exemplary embodiments of the present disclosure are not limited thereto.

For example, the driving circuit may be a data driving circuit and/or a gate driving circuit, but the exemplary embodiments of the present disclosure are not limited thereto. Wiring lines through which a control signal for controlling driving circuits is supplied may be disposed on the substrate 110. For example, the control signal may include various timing signals including a clock signal, an input data enable signal, and synchronization signals, but the exemplary embodiments of the present disclosure are not limited thereto. The control signal may be received through the pad unit PAD. For example, in the non-active area NA, link lines LL may be disposed to transmit signals. For example, driving components, such as the flexible circuit board FCB and the printed circuit board 160, may be connected to the pad unit PAD.

According to the present disclosure, the non-active area NA may include a first non-active area NA1, a bending area BA, and a second non-active area NA2. For example, the first non-active area NA1 may be an area adjacent to (for example, at least partially surrounding) at least a part of the active area AA. The bending area BA may be an area extending from at least one side, among a plurality of sides of the first non-active area NA1 and may be a bendable area. The second non-active area NA2 may be an area extending from the bending area BA and the pad unit PAD may be disposed therein. For example, the bending area BA may be in a bent state and the other areas of the substrate 110 excluding the bending area BA may be in a flat state. In this case, as the bending area BA is bent, the second non-active area NA2 may be located on a rear surface of the active area AA, but the exemplary embodiments of the present disclosure are not limited thereto.

The active area AA of the substrate 110 or the display apparatus 1000 may be configured with various shapes depending on a design of the display panel 100. For example, the active area AA may be configured with a rectangular shape formed with four rounded corners, but the exemplary embodiments of the present disclosure are not limited thereto. As another example, the active area AA may be configured with a rectangular shape formed with four right-angled corners or a circular shape, but the exemplary embodiments of the present disclosure are not limited thereto.

According to the present disclosure, a width of the second non-active area NA2 in which the plurality of pad electrodes PE is disposed may be larger than a width of the bending area BA in which only a plurality of link lines LL is disposed. Further, a width of the active area AA in which the plurality of sub pixels is disposed may be larger than a width of the bending area BA in which only a plurality of link lines LL is disposed. Even though in the drawing, it is illustrated that the width of the bending area BA is smaller than a width of the other area of the substrate 110, the shape of the substrate 110 including the bending area BA is illustrative and the exemplary embodiments of the present disclosure are not limited thereto.

Referring to FIG. 2B, a plurality of pixel driving circuits PD may be disposed in the active area AA. The plurality of pixel driving circuits PD may be circuits for driving micro LEDs of the plurality of sub pixels. Each of the plurality of pixel driving circuits PD may include a plurality of transistors including a driving transistor and a storage capacitor and supply a control signal, a power, and a driving current to the micro LEDs of the plurality of sub pixels to control an emission operation of the plurality of micro LEDs. For example, the pixel driving circuit PD may include a power line and a signal line for controlling emission on/off and/or an emission time of the micro LED. For example, the plurality of pixel driving circuits PD may be driving drivers manufactured using a metal-oxide-silicon field effect transistor (MOSFET) manufacturing process on a semiconductor substrate, but the exemplary embodiments of the present disclosure are not limited thereto. The driving driver may include a plurality of pixel driving circuits PD and drive a plurality of sub pixels.

Referring to FIG. 1 together, the flexible circuit board FCB and the printed circuit board 160 may be disposed below the display panel 100. The flexible circuit board FCB and the printed circuit board 160 may be disposed at least at one edge of the display panel 100, but the exemplary embodiments of the present disclosure are not limited thereto. One side of the flexible circuit board FCB may be attached to the display panel 100 and the other side may be attached to the printed circuit board 160, but the exemplary embodiments of the present disclosure are not limited thereto. The flexible circuit board FCB may be a flexible film, but the exemplary embodiments of the present disclosure are not limited thereto.

A pad unit PAD including a plurality of pad electrodes PE may be disposed in the second non-active area NA2. In the pad unit PAD, a driving component including one or more flexible circuit boards (or flexible films) FCB and the printed circuit board 160 may be attached or bonded. The plurality of pad electrodes PE of the pad unit PAD may be electrically connected to one or more flexible circuit boards (or flexible films) FCB and transmit various signals (or powers) from the printed circuit board 160 and the flexible circuit board (or a flexible film) FCB to the plurality of pixel driving circuits PD of the active area AA.

Referring to FIGS. 2B to 3E, the plurality of pad electrodes PE may include, for example, a plurality of crack detection pad electrodes. The plurality of crack detection pad electrodes may include one signal transmission pad electrode PE_T and a plurality of signal reception pad electrodes PE_R. Alternatively, the plurality of crack detection pad electrodes may include a plurality of signal transmission pad electrodes PE_T and one signal reception pad electrode PE_R. In addition, the plurality of crack detection pad electrodes may include a plurality of signal transmission pad electrodes PE_T and a plurality of signal reception pad electrodes PE_R corresponding to the plurality of signal transmission pad electrodes PE_T.

For example, the signal transmission pad electrode PE_T is connected to the flexible circuit board FCB to transmit a crack detection signal applied from the timing controller of the flexible circuit board FCB to the plurality of crack detection lines PCDL. However, it is not limited thereto and the signal transmission pad electrode PE_T may be applied with a crack detection signal from the timing controller of the printed circuit board 160.

For example, the signal transmission pad electrode PE_T may be connected to all the plurality of crack detection lines PCDL. Therefore, the signal transmission pad electrode PE_T may transmit the same crack detection signal to all the crack detection lines PCDL. In addition, the signal transmission pad electrode PE_T may also be referred to as a signal input pad electrode.

The plurality of signal reception pad electrodes PE_R is connected to the flexible circuit board FCB to transmit a crack detection signal which is applied through the plurality of crack detection lines PCDL to the timing controller of the flexible circuit board FCB. However, it is not limited thereto and the plurality of signal reception pad electrodes PE_R may transmit the crack detection signal to the timing controller of the printed circuit board 160.

For example, the plurality of signal reception pad electrodes PE_R may be connected to the plurality of crack detection lines PCDL, respectively.

For example, the plurality of signal reception pad electrodes PE_R may include a first signal reception pad electrodes PE_R1 connected to the first crack detection line PCDL1, a second signal reception pad electrodes PE_R2 connected to the second crack detection line PCDL2, a third signal reception pad electrodes PE_R3 connected to the third crack detection line PCDL3, a fourth signal reception pad electrodes PE_R4 connected to the fourth crack detection line PCDL4, and a fifth signal reception pad electrodes PE_R5 connected to the fifth crack detection line PCDL5. In the present disclosure, even though it is described that five signal reception pad electrodes PE_R are provided, the number of signal reception pad electrodes PE_R is not limited thereto and may vary depending on the design.

In addition, the signal reception pad electrode PE_R may also be referred to as a signal output pad electrode.

The first signal reception pad electrode PE_R1 may transmit a crack detection signal which is applied from the signal transmission pad electrode PE_T through the first crack detection line PCDL1 to the flexible circuit board FCB.

The second signal reception pad electrode PE_R2 may transmit a crack detection signal which is applied from the signal transmission pad electrode PE_T through the second crack detection line PCDL2 to the flexible circuit board FCB.

The third signal reception pad electrode PE_R3 may transmit a crack detection signal which is applied from the signal transmission pad electrode PE_T through the third crack detection line PCDL3 to the flexible circuit board FCB.

The fourth signal reception pad electrode PE_R4 may transmit a crack detection signal which is applied from the signal transmission pad electrode PE_T through the fourth crack detection line PCDL4 to the flexible circuit board FCB.

The fifth signal reception pad electrode PE_R5 may transmit a crack detection signal which is applied from the signal transmission pad electrode PE_T through the fifth crack detection line PCDL5 to the flexible circuit board FCB.

Referring to FIGS. 1 and 2A, the flexible circuit board (or flexible film) FCB may be a film on which various components are disposed on a base film having ductility. For example, driving ICs, such as a gate driver IC or a data driver IC, and a timing controller which supplies various signals to the driving IC may be disposed in the flexible circuit board (or flexible film) FCB, but the exemplary embodiments of the present disclosure are not limited thereto. The driving IC may be a component which processes data and driving signals to display images. The driving IC may be disposed by a chip on glass (COG), a chip on film (COF), or a tape carrier package (TCP) technique depending on a mounting method, but the exemplary embodiments of the present disclosure are not limited thereto. The flexible circuit board (or flexible film) FCB may be attached or bonded onto the plurality of pad electrodes PE through a conductive adhesive layer, but the exemplary embodiments of the present disclosure are not limited thereto.

The timing controller of the flexible circuit board FCB may apply a crack detection signal to the signal transmission pad electrode PE_T. Accordingly, the timing controller may read the crack detection signal which returns to each of the plurality of signal reception pad electrodes PE_R through the plurality of crack detection lines PCDL connected to the signal transmission pad electrode PE_T. Therefore, it is possible to determine whether each of the plurality of crack detection lines PCDL is cracked. Alternatively, the signals from the plurality of signal reception pad electrodes PE_R may be transferred to another component of the display apparatus in addition to the timing controller, or be transferred to outside.

The printed circuit board 160 may be a component which is electrically connected to one or more flexible circuit boards (or flexible films) FCB and supplies a signal to the driving IC. The printed circuit board 160 is disposed at one side of the flexible circuit board (or flexible film) FCB to be electrically connected to the flexible circuit board (or flexible film) FCB. On the printed circuit board 160, various components for supplying various signals to the driving IC may be disposed. For example, on the printed circuit board 160, various components, such as a timing controller, a power source, a memory, or a processor, may be disposed. For example, the printed circuit board 160 may include a power management integrated circuit (PMIC), but the exemplary embodiments of the present disclosure are not limited thereto.

The printed circuit board 160 may include at least one hole 180, but the exemplary embodiments of the present disclosure are not limited thereto. An internal component which senses ambient light or temperature to be supplied to a plurality of sensors may be disposed in an area corresponding to at least one hole 180. For example, the internal component may include an ambient light sensor (ALS) or a temperature sensor, but the exemplary embodiments of the present disclosure are not limited thereto. For example, the hole 180 may be a transmission hole, but the exemplary embodiments of the present disclosure are not limited thereto.

Referring to FIGS. 2A to 3E together, the plurality of crack detection lines PCDL may be disposed in the non-active area NA. For example, the plurality of crack detection lines PCDL may be disposed so as to surround at least a part of the active area AA in the first non-active area NA1. The plurality of crack detection lines PCDL may be connected to the plurality of pad electrodes PE in the second non-active area NA2. Therefore, the plurality of crack detection lines PCDL may be disposed in an area of the first non-active area NA1 excluding a part of an area overlapping the second non-active area NA2. The plurality of crack detection lines PCDL is disposed at the outermost periphery of the first non-active area NA1 to detect whether the display apparatus 1000 is cracked.

For example, referring to FIG. 2A, the plurality of crack detection lines PCDL may be disposed so as to at least partially overlap each other. The plurality of crack detection lines PCDL is connected to the same signal transmission pad electrode PE_T to be disposed along the periphery of the substrate 110. Therefore, the plurality of crack detection lines PCDL may be disposed so as to overlap each other before being connected to different signal reception pad electrodes PE_R, but is not limited thereto.

Referring to FIGS. 2A to 3E, one ends of the plurality of crack detection lines PCDL may be connected to the flexible circuit board FCB through the signal transmission pad electrode PE_T. The other ends of the plurality of crack detection lines PCDL may be connected to the flexible circuit board FCB through the signal reception pad electrode PE_R. Areas between one ends of the plurality of crack detection lines PCDL and the other ends of the plurality of crack detection lines PCDL may be disposed along the outer periphery of the first non-active area NA1. For example, the plurality of crack detection lines PCDL may extend from the signal transmission pad electrode PE_T toward the signal reception pad electrode PE_R along the periphery of the substrate 110.

The plurality of crack detection lines PCDL may transmit a crack detection signal applied from the signal transmission pad electrode PE_T to the signal reception pad electrode PE_R. For example, the plurality of crack detection lines PCDL may be connected to the same signal transmission pad electrode PE_T and may also be connected to different signal reception pad electrodes PE_R. For example, if any crack detection line PCDL, among the plurality of crack detection lines PCDL, is disconnected, a crack detection signal may not be transmitted to the signal reception pad electrode PE_R connected to the corresponding crack detection line PCDL. Therefore, it is possible to detect whether the corresponding crack detection line PCDL is cracked.

For example, the plurality of crack detection lines PCDL may include a first crack detection line PCDL1, a second crack detection line PCDL2, a third crack detection line PCDL3, a fourth crack detection line PCDL4, and a fifth crack detection line PCDL5. In the present disclosure, even though it is described that five crack detection lines are provided, the number of crack detection lines is not limited thereto and may vary depending on the design.

One end of each of the first crack detection line PCDL1, the second crack detection line PCDL2, the third crack detection line PCDL3, the fourth crack detection line PCDL4, and the fifth crack detection line PCDL5 may be connected to the same signal transmission pad electrode PE_T. Hereinafter, the first crack detection line PCDL1, the second crack detection line PCDL2, the third crack detection line PCDL3, the fourth crack detection line PCDL4, and the fifth crack detection line PCDL5 may receive the same crack detection signal from the flexible circuit board FCB through the signal transmission pad electrode PE_T.

In addition, the other ends of the first crack detection line PCDL1, the second crack detection line PCDL2, the third crack detection line PCDL3, the fourth crack detection line PCDL4, and the fifth crack detection line PCDL5 may be connected to the flexible circuit board FCB through different signal reception pad electrodes PE_R.

For example, the first crack detection line PCDL1 may transmit a signal applied from the signal transmission pad electrode PE_T to the first signal reception pad electrode PE_R1. Therefore, the timing controller of the flexible circuit board FCB reads or determines whether the first signal reception pad electrode PE_R1 receives the crack detection signal to detect whether the first crack detection line PCDL1 is cracked. However, it is not limited thereto and the timing controller of the printed circuit board 160 may determine whether the first signal reception pad electrode PE_R1 receives the crack detection signal.

For example, the second crack detection line PCDL2 may transmit a signal applied from the signal transmission pad electrode PE_T to the second signal reception pad electrode PE_R2. Therefore, the timing controller of the flexible circuit board FCB reads or determines whether the second signal reception pad electrode PE_R2 receives the crack detection signal to detect whether the second crack detection line PCDL2 is cracked. However, it is not limited thereto and the timing controller of the printed circuit board 160 may determine whether the second signal reception pad electrode PE_R2 receives the crack detection signal.

For example, the third crack detection line PCDL3 may transmit a signal applied from the signal transmission pad electrode PE_T to the third signal reception pad electrode PE_R3. Therefore, the timing controller of the flexible circuit board FCB reads or determines whether the third signal reception pad electrode PE_R3 receives the crack detection signal to detect whether the third crack detection line PCDL3 is cracked. However, it is not limited thereto and the timing controller of the printed circuit board 160 may determine whether the third signal reception pad electrode PE_R3 receives the crack detection signal.

For example, the fourth crack detection line PCDL4 may transmit a signal applied from the signal transmission pad electrode PE_T to the fourth signal reception pad electrode PE_R4. Therefore, the timing controller of the flexible circuit board FCB reads or determines whether the fourth signal reception pad electrode PE_R4 receives the crack detection signal to detect whether the fourth crack detection line PCDL4 is cracked. However, it is not limited thereto and the timing controller of the printed circuit board 160 may determine whether the fourth signal reception pad electrode PE_R4 receives the crack detection signal.

For example, the fifth crack detection line PCDL5 may transmit a signal applied from the signal transmission pad electrode PE_T to the fifth signal reception pad electrode PE_R5. Therefore, the timing controller of the flexible circuit board FCB reads or determines whether the fifth signal reception pad electrode PE_R5 receives the crack detection signal to detect whether the fifth crack detection line PCDL5 is cracked. However, it is not limited thereto and the timing controller of the printed circuit board 160 may determine whether the fifth signal reception pad electrode PE_R5 receives the crack detection signal.

In addition, lengths of the plurality of crack detection lines PCDL may be different from each other. The plurality of crack detection lines PCDL extends from the same signal transmission pad electrode PE_T toward different signal reception pad electrodes PE_R so that the lengths of the plurality of crack detection lines PCDL may be different from each other according to the position of the corresponding signal reception pad electrode PE_R.

For example, referring to FIGS. 2B to 3E, the fifth signal reception pad electrode PE_R5 may be disposed at the outermost side among the plurality of signal reception pad electrodes PE_R. Therefore, the length of the fifth crack detection line PCDL5 which is connected to the fifth signal reception pad electrode PE_R5 may be the shortest. In contrast, the first signal reception pad electrode PE_R1 may be disposed relatively in the center of the second non-active area NA2. Therefore, the length of the first crack detection line PCDL1 which is connected to the first signal reception pad electrode PE_R1 may be the longest, but is not limited thereto.

Referring to FIG. 1, the polarization layer 293 may be disposed on the display panel 100. The polarization layer 293 may suppress or reduce the influence on the micro LED caused by light generated from an external light source and entering the display panel 100. In another example, an adhesive layer may be disposed between the polarization layer 293 and the display panel 100.

The cover member 120 may be disposed on the polarization layer 293. The cover member 120 may be a member for protecting the display panel 100. The adhesive layer 295 may be disposed between the polarization layer 293 and the cover member 120. The cover member 120 may be attached to the display panel 100 using the adhesive layer 295. The adhesive layer 295 may include an optically clear adhesive (OCA), an optically clear resin (OCR), or a pressure sensitive adhesive (PSA), but the exemplary embodiments of the present disclosure are not limited thereto.

The support substrate 170 may be disposed between the display panel 100 and the printed circuit board 160. The support substrate 170 may reinforce a rigidity of the display panel 100. The support substrate 170 may be a back plate, but the exemplary embodiments of the present disclosure are not limited thereto. The support substrate 170 may be omitted when necessary.

Referring to FIGS. 1 to 3E, the plurality of link lines LL may be disposed in the non-active area NA. The plurality of link lines LL may be wiring lines which transmit various signals from one or more flexible circuit boards (or flexible films) FCB and the printed circuit board 160 to the active area AA. The plurality of link lines LL extends from the plurality of pad electrodes PE of the second non-active area NA2 toward the bending area BA and the first non-active area NA1 to be electrically connected to the plurality of driving lines VL of the active area AA. The plurality of pixel driving circuits PD is supplied with signals from one or more flexible films (or flexible films) FCB and the printed circuit board 160 through the driving line VL of the active area AA and the link line LL of the non-active area NA to be driven.

For example, the plurality of driving lines VL may be wiring lines for transmitting a signal output from the flexible circuit board (or flexible film) FCB and the printed circuit board 160 to the plurality of pixel driving circuits PD together with the plurality of link lines LL. The plurality of driving lines VL is disposed in the active area AA to be electrically connected to each of the plurality of pixel driving circuits PD. The plurality of driving lines VL extends toward the non-active area NA from the active area AA to be electrically connected to the plurality of link lines LL. Accordingly, a signal output from the flexible circuit board (or flexible film) FCB and the printed circuit board 160 may be transmitted to each of the plurality of pixel driving circuits PD through the plurality of link lines LL and the plurality of driving lines VL.

As the bending area BA is bent, a part of the plurality of link lines LL may be bent together. A stress is concentrated in the bent part of the link line LL, which causes a crack on the link line LL. Accordingly, the plurality of link lines LL may include a conductive material having excellent ductility to reduce the crack caused when the bending area BA is bent. For example, the plurality of link lines LL may include a conductive material having excellent ductility, such as gold (Au), silver (Ag), or aluminum (Al), but the exemplary embodiments of the present disclosure are not limited thereto. Further, the plurality of link lines LL may include one of various conductive materials used for the active area AA. For example, the plurality of link lines LL may include molybdenum (Mo), chrome (Cr), titanium (Ti), nickel (Ni), neodymium (Nd), copper (Cu), and an alloy of silver (Ag) and magnesium (Mg) or an alloy thereof, but the exemplary embodiments of the present disclosure are not limited thereto. The plurality of link lines LL may include a multi-layered structure (such as a double layer structure or a triple layer structure) including various conductive materials. For example, the plurality of link lines LL may be configured with a triple-layered structure of titanium (Ti)/aluminum (Al)/titanium (Ti), but the exemplary embodiments of the present disclosure are not limited thereto.

The plurality of link lines LL may be configured with various shapes to reduce a stress. At least some of the plurality of link lines LL disposed on the bending area BA may extend in the same direction as an extending direction of the bending area BA or extend in a different direction from the extending direction of the bending area BA to reduce a stress. For example, when the bending area BA extends in one direction toward the second non-active area NA2 from the first non-active area NA1, at least a part of the link line LL disposed on the bending area BA may extend in an inclined direction from one direction. As another example, at least some of the plurality of link lines LL may include various shapes of patterns. For example, at least some of the plurality of link lines LL disposed on the bending area BA may have a shape in which a conductive pattern having at least one shape of a diamond shape, a rhombus shape, a trapezoidal wave shape, a triangular wave shape, a sawtooth wave shape, a sine wave shape, a circular shape, an omega (Ω) shape is repeatedly disposed. However, the exemplary embodiments of the present disclosure are not limited thereto. Accordingly, in order to minimize or reduce a stress concentrated on the plurality of link lines LL and a crack caused thereby, a shape of the plurality of link lines LL may be various shapes including the above-mentioned shapes, but the exemplary embodiments of the present disclosure are not limited thereto.

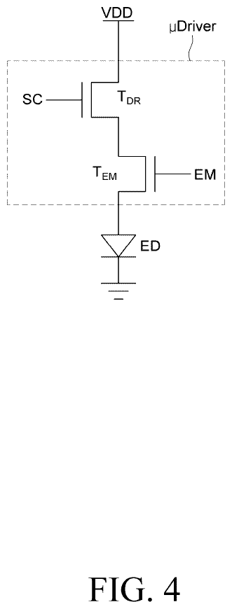

FIG. 4 is a view illustrating a circuit structure according to an exemplary embodiment of the present disclosure.

A pixel driving circuit PD may include a micro driver (μDriver). The micro LED (ED) is electrically connected to the micro driver (μDriver) of the pixel driving circuit PD to be driven. Even though in FIG. 4, it is illustrated that one micro LED (ED) is connected to one micro driver (μDriver), the present disclosure is not limited thereto. For example, eight micro LEDs (ED) may be connected to one micro driver (μDriver). As another example, 16 micro LEDs (ED) may be connected to one micro driver (μDriver) or 32 micro LEDs (ED) or 64 micro LEDs (ED) may be simultaneously connected to one micro driver (μDriver).

One micro driver (μDriver) may include a driving transistor T_{DR} and an emission transistor T_{EM}, but the exemplary embodiments of the present disclosure are not limited thereto. For example, one or more other transistors and one or more capacitors may be included in the micro driver (μDriver). For example, 2T1C, 3T1C, 4T1C, 5T1C, 3T2C, 4T2C, 5T2C, 6T2C, 7T1C, 7T2C, 8T2C 8T2C structures, etc., are also possible for the micro driver (μDriver).

For example, a high potential power voltage VDD may be applied to a first electrode of the driving transistor T_{DR} and a first electrode of the emission transistor T_{EM} may be connected to a second electrode of the driving transistor T_{DR}, and a scan signal SC may be applied to a gate electrode of the driving transistor T_{DR}. The scan signal SC applied to the gate electrode of the driving transistor T_{DR} is a direct current (DC) power and a fixed reference voltage may be applied in every frame, but the exemplary embodiments of the present disclosure are not limited thereto.

The second electrode of the driving transistor T_{DR} may be connected to a first electrode of the emission transistor T_{EM}, the micro LED (ED) may be connected to a second electrode of the emission transistor T_{EM}, and the emission signal EM may be applied to a gate electrode of the emission transistor T_{EM}. The emission signal EM applied to the gate electrode of the emission transistor T_{EM} may be a pulse width modulation signal which changes in every frame, but the exemplary embodiments of the present disclosure are not limited thereto.

A first electrode of the micro LED (ED) may be connected to the second electrode of the emission transistor T_{EM} and a second electrode may be connected to the ground. For example, the first electrode may be an anode electrode and the second electrode may be a cathode electrode, but the exemplary embodiments of the present disclosure are not limited thereto.

Each of the driving transistor T_{DR} and the emission transistor T_{EM} may be an n-type transistor or a p-type transistor.

The driving transistor T_{DR} may be turned on by a scan signal SC applied from the timing controller T-CON or the driving IC such as the gate driving IC to the micro driver (μDriver) and the emission transistor T_{EM} may be turned on by the emission signal EM. By doing this, the driving current is applied to the micro LED (ED) via the driving transistor T_{DR} and the emission transistor T_{EM} by the high potential power voltage VDD applied to the first electrode of the driving transistor T_{DR} so that the micro LED (ED) may emit light.

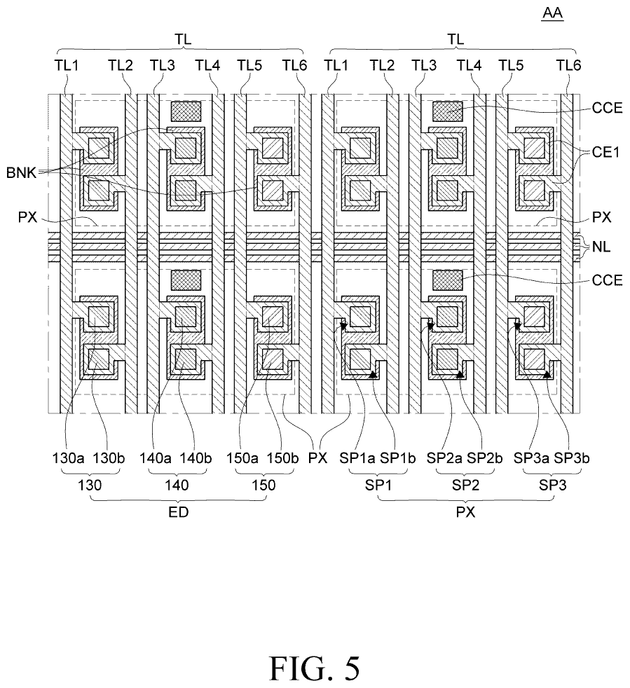

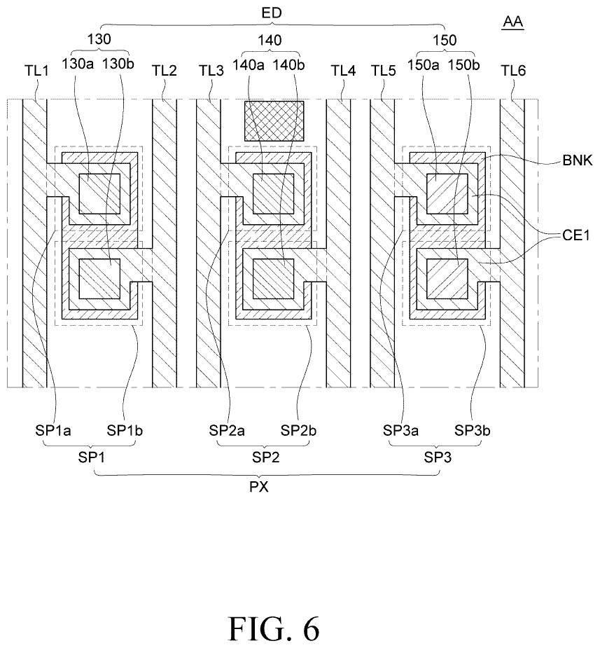

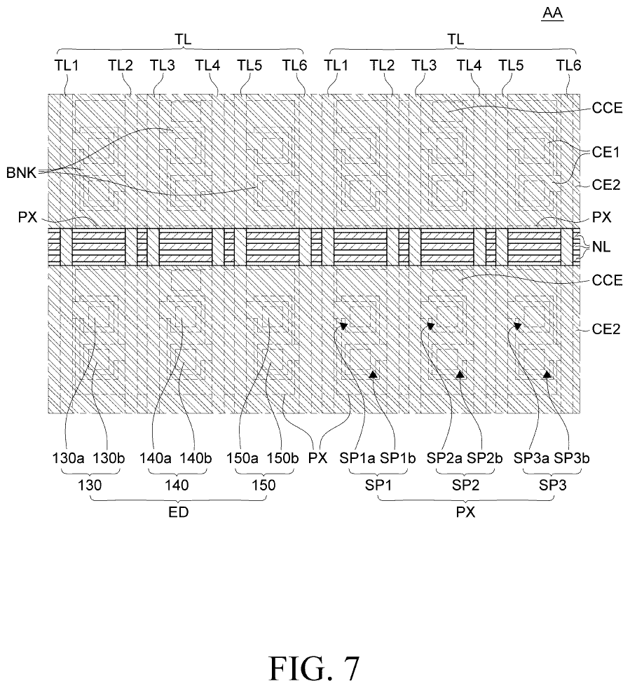

FIGS. 5 to 7 are plan views of a display apparatus according to an exemplary embodiment of the present disclosure. For example, FIG. 5 is an enlarged plan view of an active area including a plurality of pixels. For example, FIG. 6 is an enlarged plan view of an active area including one pixel. For example, FIG. 7 is an enlarged plan view of an active area including a plurality of pixels. In FIGS. 5 and 6, only a plurality of signal lines TL, a plurality of communication lines NL, a plurality of first electrodes CE1, a plurality of banks BNK, and a plurality of micro LEDs (ED) are illustrated, but the exemplary embodiments of the present disclosure are not limited thereto. FIG. 7 is an enlarged plan view in which a plurality of second electrodes CE2 is additionally disposed in FIG. 5.

Referring to FIGS. 5 and 6, a plurality of pixels PX each of which is configured by a plurality of sub pixels may be disposed in the active area AA. Each of the plurality of sub pixels may include a micro LED (ED) and independently emit light. The plurality of sub pixels may be disposed in a matrix by forming a plurality of rows and a plurality of columns, but the exemplary embodiments of the present disclosure are not limited thereto.

The plurality of sub pixels may include a first sub pixel SP1, a second sub pixel SP2, and a third sub pixel SP3. For example, any one of the first sub pixel SP1, the second sub pixel SP2, and the third sub pixel SP3 may be a red sub pixel, another may be a green sub pixel, and the third may be a blue sub pixel. However, the present disclosure is not limited thereto. In another example, each of the sub pixels may be a white sub pixel. The types of the plurality of sub pixels are illustrative, but the exemplary embodiments of the present disclosure are not limited thereto. For example, the plurality of sub pixels may include more or less main sub pixels depending on the arrangement manner of the pixels.

Each of the plurality of pixels PX may include one or more first sub pixels SP1, one or more second sub pixels SP2, and one or more third sub pixels SP3. For example, one pixel PX may include one pair of first sub pixels SP1, one pair of second sub pixels SP2, and one pair of third sub pixels SP3. One pair of first sub pixels SP1 may include a 1-1-th sub pixel SP1a and a 1-2-th sub pixel SP1b. One pair of second sub pixels SP2 may include a 2-1-th sub pixel SP2a and a 2-2-th sub pixel SP2b. One pair of third sub pixels SP3 may include a 3-1-th sub pixel SP3a and a 3-2-th sub pixel SP3b. For example, one pixel PX may include a 1-1-th sub pixel SP1a and a 1-2-th sub pixel SP1b, a 2-1-th sub pixel SP2a and a 2-2-th sub pixel SP2b, and a 3-1-th sub pixel SP3a and a 3-2-th sub pixel SP3b, but the exemplary embodiments of the present disclosure are not limited thereto.

The plurality of sub pixels which forms one pixel PX may be disposed in various ways. For example, in one pixel PX, one pair of first sub pixels SP1 may be disposed on the same column, one pair of second sub pixels SP2 may be disposed on the same column, and one pair of third sub pixels SP3 may be disposed on the same column. The first sub pixels SP1, the second sub pixels SP2, and the third sub pixels SP3 may be disposed on the same row. A number and a placement of the plurality of sub pixels which configures one pixel PX are illustrative, but the exemplary embodiments of the present disclosure are not limited thereto.

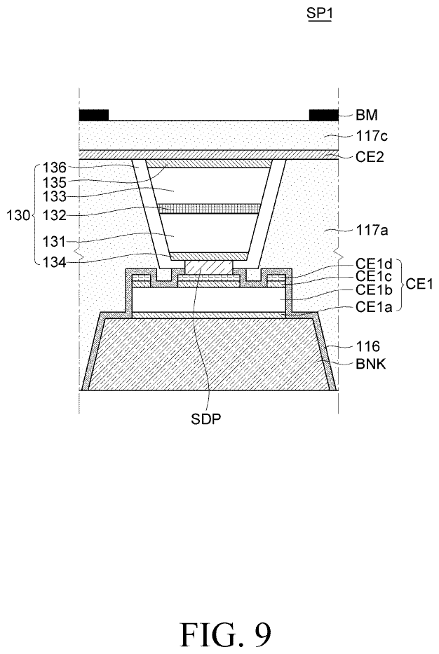

The plurality of signal lines TL may be disposed in an area between the plurality of sub pixels. The plurality of signal lines TL may extend in the column direction between the plurality of sub pixels. The plurality of signal lines TL may be wiring lines which transmit an anode voltage from the pixel driving circuit PD to the plurality of sub pixels. For example, the plurality of signal lines TL may be electrically connected to the plurality of pixel driving circuits PD and the first electrodes CE1 of the plurality of sub pixels. The anode voltage output from the pixel driving circuit PD may be transmitted to the first electrode CE1 of the plurality of sub pixels through the plurality of signal lines TL. For example, the first electrode CE1 may be an electrode which is electrically connected to the anode electrode 134 of the micro LED (ED) as illustrated in FIG. 9 to be described below. Therefore, the anode voltage from the signal line TL may be transmitted to the anode electrode 134 of the micro LED (ED) through the first electrode CE1.

Accordingly, instead of the plurality of transistors and storage capacitors formed in each of the plurality of sub pixels, a pixel driving circuit PD in which a plurality of pixel circuits is integrated is used to simplify the structure of the display apparatus 1000. Further, a circuit which is disposed in each of the plurality of sub pixels is integrated in one pixel driving circuit PD so that highly efficient low power driving is possible.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to one pair of first sub pixels SP1, respectively. The third signal line TL3 and the fourth signal line TL4 may be electrically connected to one pair of second sub pixels SP2, respectively. The fifth signal line TL5 and the sixth signal line TL6 may be electrically connected to one pair of third sub pixels SP3, respectively.

The first signal line TL1 may be disposed on one of one pair of first sub pixels SP1 and the second signal line TL2 may be disposed on the other one of one pair of first sub pixels SP1. The first signal line TL1 may electrically connect one first sub pixel SP1, between one pair of first sub pixels SP1, for example, to the first electrode CE1 of the 1-1-th sub pixel SP1a. The second signal line TL2 may electrically connect the other first sub pixel SP1, between one pair of first sub pixels SP1, for example, to the first electrode CE1 of the 1-2-th sub pixel SP1b.

The third signal line TL3 may be disposed on one of one pair of second sub pixels SP2 and the fourth signal line TL4 may be disposed on the other one of one pair of second sub pixels SP2. For example, the third signal line TL3 may be disposed to be adjacent to the second signal line TL2. The third signal line TL3 may electrically connect one second sub pixel SP2, between one pair of second sub pixels SP2, for example, to the first electrode CE1 of the 2-1-th sub pixel SP2a. The fourth signal line TL4 may electrically connect the other second sub pixel SP2, between one pair of second sub pixels SP2, for example, to the first electrode CE1 of the 2-2-th sub pixel SP2b.

The fifth signal line TL5 may be disposed on one of one pair of third sub pixels SP3 and the sixth signal line TL6 may be disposed on the other one of one pair of third sub pixels SP3. For example, the fifth signal line TL5 may be disposed to be adjacent to the fourth signal line TL4. The sixth signal line TL6 may be disposed to be adjacent to the first signal line TL1 connected to the adjacent pixel PX. The fifth signal line TL5 may electrically connect one third sub pixel SP3, between one pair of third sub pixels SP3, for example, to the first electrode CE1 of the 3-1-th sub pixel SP3a. The sixth signal line TL6 may electrically connect the other third sub pixel SP3, between one pair of third sub pixels SP3, for example, to the first electrode CE1 of the 3-2-th sub pixel SP3b.

The plurality of signal lines TL may be formed of a conductive material. For example, the plurality of signal lines TL may include a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the exemplary embodiments of the present disclosure are not limited thereto. As another example, the plurality of signal lines TL may be formed with a multi-layered structure of conductive materials. For example, the plurality of signal lines TL may be formed with a multi-layered structure of titanium (Ti)/aluminum (Al)/titanium (Ti)/indium tin oxide (ITO), but the exemplary embodiments of the present disclosure are not limited thereto.

A plurality of communication lines NL may be disposed in an area between the plurality of pixels PX. The plurality of communication lines NL may be disposed to extend in the row direction in an area between the plurality of pixels PX. The plurality of communication lines NL is disposed in the area between the plurality of second electrodes CE2 and may not overlap the plurality of second electrodes CE2. For example, the plurality of communication lines NL may be wiring lines used for short distance communication, such as near field communication (NFC). The plurality of communication lines NL may serve as antennas. For example, the plurality of communication lines NL may be a plurality of connection lines, but the exemplary embodiments of the present disclosure are not limited thereto.

According to the present disclosure, a bank BNK may be disposed in each of the plurality of sub pixels. The plurality of banks BNK may be structures in which the plurality of micro LEDs (ED) is seated. The plurality of banks BNK may guide a position of the plurality of micro LEDs (ED) during a transfer process of transferring the plurality of micro LEDs (ED) to the display apparatus 1000. The plurality of micro LEDs (ED) may be transferred onto the plurality of banks BNK in the transfer process of the plurality of micro LEDs (ED). The plurality of banks BNK may be a bank pattern or a structure, but the exemplary embodiments of the present disclosure are not limited thereto.

A bank BNK of the first sub pixel SP1, a bank BNK of the second sub pixel SP2, and a bank BNK of the third sub pixel SP3 may be disposed to be spaced apart from each other. The bank BNK of the first sub pixel SP1, the bank BNK of the second sub pixel SP2, and the bank BNK of the third sub pixel SP3 may be configured to be separated from each other. Therefore, the banks BNK of the first sub pixel SP1, the second sub pixel SP2, and the third sub pixel SP3 to which different types of micro LEDs (ED) are transferred may be easily identified.

The bank BNK of the 1-1-th sub pixel SP1a and the bank BNK of the 1-2-th sub pixel SP1b may be connected to each other or spaced apart or separated from each other. For example, in consideration of a design, such as a transfer process requirement, the bank BNK of the 1-1-th sub pixel SP1a and the bank BNK of the 1-2-th sub pixel SP1b in which the same type of micro LED (ED) is disposed may be connected to each other or spaced apart or separated from each other. The bank BNK of the 2-1-th sub pixel SP2a and the bank BNK of the 2-2-th sub pixel SP2b may be connected to each other, spaced apart or separated from each other. The bank BNK of the 3-1-th sub pixel SP3a and the bank BNK of the 3-2-th sub pixel SP3b may be connected to each other, spaced apart or separated from each other. Accordingly, the banks BNK of one pair of first sub pixels SP1, the banks BNK of one pair of second sub pixels SP2, and the banks BNK of one pair of third sub pixels SP3 may be formed in various forms such as an island shape, but the exemplary embodiments of the present disclosure are not limited thereto.

For example, the plurality of banks BNK may be formed of an organic insulating material. The plurality of banks BNK may include a single layer or a double layer of an organic insulating material. For example, the plurality of banks BNK may include a photo resist, polyimide (PI), or acrylic material, but the exemplary embodiments of the present disclosure are not limited thereto.

The first electrode CE1 may be disposed in each of the plurality of sub pixels. The first electrode CE1 may be disposed on the bank BNK. The first electrode CE1 may be electrically connected to one signal line TL, among the plurality of signal lines TL, and thus may also be referred to as first connection electrode. At least a part of the first electrode CE1 extends to the outside of the bank BNK to be electrically connected to the signal line TL which is the most adjacent to the first electrode CE1. For example, a part of the first electrode CE1 of the 1-1-th sub pixel SP1a extends to one area of the 1-1-th sub pixel SP1a to be electrically connected to the first signal line TL1. A part of the first electrode CE1 of the 1-2-th sub pixel SP1b extends to the other area of the 1-2-th sub pixel SP1b to be electrically connected to the second signal line TL2. A part of the first electrode CE1 of the 2-1-th sub pixel SP2a extends to one area of the 2-1-th sub pixel SP2a to be electrically connected to the third signal line TL3. A part of the first electrode CE1 of the 2-2-th sub pixel SP2b extends to the other area of the 2-2-th sub pixel SP2b to be electrically connected to the fourth signal line TL4. A part of the first electrode CE1 of the 3-1-th sub pixel SP3a extends to one area of the 3-1-th sub pixel SP3a to be electrically connected to the fifth signal line TL5. A part of the first electrode CE1 of the 3-2-th sub pixel SP3b extends to the other area of the 3-2-th sub pixel SP3b to be electrically connected to the sixth signal line TL6. As shown in FIG. 5, the parts of the first electrodes CE1 of each of the 1-1th sub pixels SP1a in different rows, the 2-1th sub pixels SP2a in different rows and the 3-1th sub pixels SP3a in different rows may be aligned with each other in the column direction so as to be electrically connected to a same signal line. Similarly, the parts of the first electrodes CE1 of each of the 1-2th sub pixels SP1b in different rows, the 2-2th sub pixels SP2b in different rows and the 3-2th sub pixels SP3b in different rows may be aligned with each other in the column direction so as to be electrically connected to a same signal line.

The first electrode CE1 may be electrically connected to the anode electrode 134 of the micro LED (ED) and transmit an anode voltage from the pixel driving circuit PD to the micro LED (ED) through the signal line TL. Different voltages may be applied to the first electrodes CE1 of the plurality of sub pixels depending on the image to be displayed. For example, different voltages may be applied to the first electrodes CE1 of the plurality of sub pixels. Therefore, the first electrode CE1 may be a pixel electrode, but the exemplary embodiments of the present disclosure are not limited thereto.

The first electrode CE1 may include a conductive material. For example, the first electrode CE1 may be integrally configured with the plurality of signal lines TL. For example, the first electrode CE1 may include the same conductive material as the plurality of signal lines TL, but the exemplary embodiments of the present disclosure are not limited thereto. For example, the first electrode CE1 may include a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the exemplary embodiments of the present disclosure are not limited thereto. As another example, the first electrode CE1 may include a multi-layered structure of conductive materials. For example, the plurality of first electrodes CE1 may include a multi-layered structure of titanium (Ti)/aluminum (Al)/titanium (Ti)/indium tin oxide (ITO), but the exemplary embodiments of the present disclosure are not limited thereto.

The micro LED (ED) may be disposed in each of the plurality of sub pixels. The plurality of micro LEDs (ED) may be any one of a light-emitting diode or a micro light-emitting diode (micro LED), but the exemplary embodiments of the present disclosure are not limited thereto. The plurality of micro LEDs (ED) may be disposed on the bank BNK and the first electrode CE1. The plurality of micro LEDs (ED) may be disposed on the first electrode CE1 and may be electrically connected to the first electrode CE1. Accordingly, the micro LED (ED) is applied with an anode voltage from the pixel driving circuit PD through the signal line TL and the first electrode CE1 to emit light.

The plurality of micro LEDs (ED) may include a first micro LED 130, a second micro LED 140, and a third micro LED 150. The first micro LED 130 may be disposed in the first sub pixel SP1. The second micro LED 140 may be disposed in the second sub pixel SP2. The third micro LED 150 may be disposed in the third sub pixel SP3. For example, any one of the first micro LED 130, the second micro LED 140, and the third micro LED 150 may be a red micro LED, another may be a green micro LED, and the third may be a blue micro LED, but the exemplary embodiments of the present disclosure are not limited thereto. Therefore, red light, green light, and blue light emitted from the plurality of micro LEDs (ED) are combined to implement various color light including white. The types of the plurality of micro LEDs (ED) are illustrative, but the exemplary embodiments of the present disclosure are not limited thereto.

The first micro LED 130 may include a 1-1-th micro LED 130a disposed in the 1-1-th sub pixel SP1a and a 1-2-th micro LED 130b disposed in the 1-2-th sub pixel SP1b. The second micro LED 140 may include a 2-1-th micro LED 140a disposed in the 2-1-th sub pixel SP2a and a 2-2-th micro LED 140b disposed in the 2-2-th sub pixel SP2b. The third micro LED 150 may include a 3-1-th micro LED 150a disposed in the 3-1-th sub pixel SP3a and a 3-2-th micro LED 150b disposed in the 3-2-th sub pixel SP3b.

Referring to FIGS. 5, 6 and 7 together, the second electrode CE2 may be disposed in each of the plurality of sub pixels. The second electrode CE2 may be disposed on the micro LED (ED). The second electrode CE2 may be electrically connected to the pixel driving circuit PD through the plurality of contact electrodes CCE.

For example, the second electrode CE2 may be electrically connected to the cathode electrode 135 of the micro LED (ED) to transmit a cathode voltage from the pixel driving circuit PD to the micro LED (ED). The same cathode voltage may be applied to the second electrodes CE2 of the plurality of sub pixels. For example, the same voltage may be applied to the second electrode CE2 of each of the plurality of sub pixels and the cathode electrode 135 of the micro LED (ED). Therefore, the second electrode CE2 may be a common electrode, but the exemplary embodiments of the present disclosure are not limited thereto.

At least some of the plurality of sub pixel may share the second electrode CE2. At least some of the second electrodes CE2 of the plurality of sub pixels may be electrically connected to each other. As the same voltage is applied to the second electrode CE2, the second electrodes CE2 of at least some of sub pixels may be shared to be used. For example, the second electrodes CE2 of at least some pixels PX, among the plurality of pixels PX disposed on the same row, may be connected to each other. For example, one second electrode CE2 may be disposed in the plurality of pixels PX. One second electrode CE2 may be disposed in every n sub pixels.

For example, some of the second electrodes CE2 of the plurality of sub pixels may be disposed to be spaced apart or separated from each other. For example, a second electrode CE2 connected to pixels PX in an n-th row and a second electrode CE2 connected to pixels PX in an n+1-th row may be disposed to be spaced apart or separated from each other. For example, the plurality of second electrodes CE2 may be disposed to be spaced apart from each other with the plurality of communication lines NL extending in the row direction therebetween. Accordingly, the number of the plurality of sub pixels may be larger than the number of the plurality of second electrodes CE2. As another example, all the second electrodes CE2 of the plurality of sub pixels are connected to each other so that only one second electrode CE2 may be disposed on the substrate 110, but the exemplary embodiments of the present disclosure are not limited thereto.

The plurality of second electrodes CE2 may include a transparent conductive material, but the exemplary embodiments of the present disclosure are not limited thereto. The plurality of second electrodes CE2 may include a transparent conductive material so that light emitted from the micro LED (ED) may travel toward the top of the second electrode CE2. For example, the second electrode CE2 may include a transparent conductive material, such as indium tin oxide (ITO), indium zinc oxide (IZO), indium gallium zinc oxide (IGZO), but the exemplary embodiments of the present disclosure are not limited thereto.

A plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap a plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 to transmit a cathode voltage from the pixel driving circuit PD to the second electrode CE2.

For example, the plurality of micro LEDs is formed on the wafer and the micro LED is transferred onto the substrate 110 of the display apparatus 1000 to manufacture the display apparatus 1000. However, during the process of transferring the plurality of micro LEDs (ED) having a micro size from the wafer to the substrate 110, various defects may be caused. For example, in some sub pixels, a non-transfer defect in which the micro LED is not transferred may occur and in the other sub pixels, a defect that the micro LED (ED) is transferred in a wrong position may occur due to the alignment error. Further, even though the transfer process is normally performed, the transferred micro LED (ED) may be defective. Accordingly, in consideration of the defects during the transfer process of the plurality of micro LEDs (ED), a plurality of same type micro LEDs may be transferred in one sub pixel. A lighting test for the plurality of micro LEDs (ED) is performed and only one micro LED (ED) which is finally determined to be normal may be used.

For example, the 1-1-th micro LED 130a and the 1-2-th micro LED 130b are transferred to one pixel PX together and defects thereof may be tested. If both the 1-1-th micro LED 130a and the 1-2-th micro LED 130b are determined to be normal, only the 1-1-th micro LED 130a may be used, but the 1-2-th micro LED 130b may not be used. As another example, if only the 1-2-th micro LED 130b between the 1-1-th micro LED 130a and the 1-2-th micro LED 130b is determined to be normal, the 1-1-th micro LED 130a may not be used, but only the 1-2-th micro LED 130b may be used. Accordingly, even though the plurality of same type micro LEDs (ED) is transferred to one pixel PX, finally, only one micro LED (ED) may be used.

Therefore, any one of one pair of micro LEDs (ED) may be a main (or primary) micro LED (ED) and the other micro LED (ED) may be a redundancy micro LED (ED). The redundancy micro LED (ED) may be an extra micro LED (ED) which is transferred to prepare for a defect of the main micro LED (ED). When the main micro LED (ED) is defective, the redundancy micro LED (ED) may be used instead. Accordingly, the main micro LED (ED) and the redundancy micro LED (ED) are transferred together to one pixel PX so that the degradation of the display quality due to the defects of the main micro LED (ED) and the redundancy micro LED (ED) may be minimized or reduced.

For example, a 1-1-th micro LED 130a, a 2-1-th micro LED 140a, and a 3-1-th micro LED 150a which are transferred into one pixel PX may be used as main micro LEDs (ED) and a 1-2-th micro LED 130b, a 2-2-th micro LED 140b, and a 3-2-th micro LED 150b may be used as redundancy micro LEDs (ED).

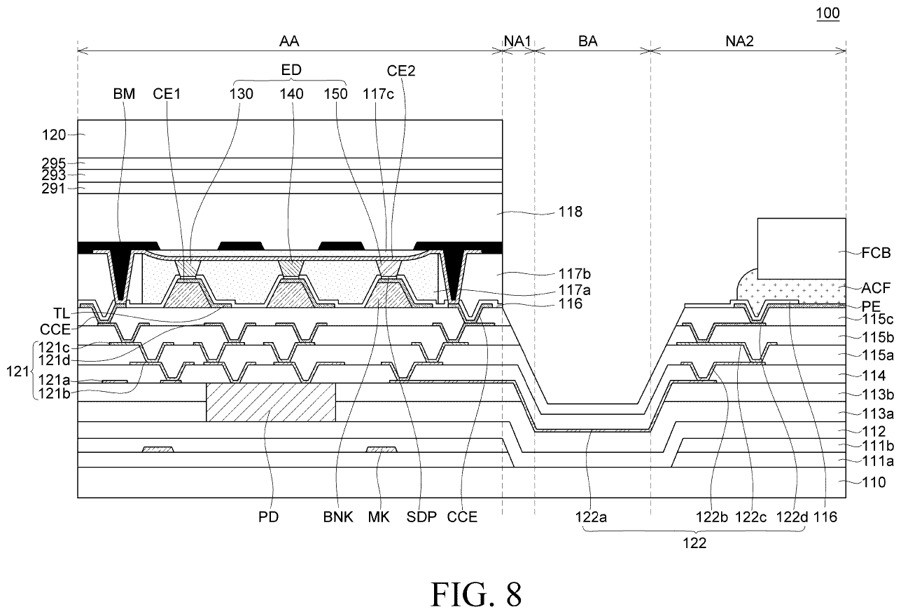

FIG. 8 is a cross-sectional view taken along VIII-VIII′ of FIG. 2B. FIG. 9 is a cross-sectional view of a display apparatus according to an exemplary embodiment of the present disclosure. FIG. 8 is a cross-sectional view of a display apparatus according to an exemplary embodiment of the present disclosure. For example, FIG. 8 is a cross-sectional view of an active area AA, a first non-active area NA1, a bending area BA, and a second non-active area NA2. For example, FIG. 9 is an enlarged cross-sectional view of a first sub pixel. In addition, for the convenience of illustration, in FIG. 2B, it is illustrated that a cross-sectional line of VIII-VIII′ and a driving line VL and a link line LL do not overlap, but the cross-sectional line VIII-VIII′ of FIG. 2B is provided to represent the same position as the driving line VL and the link line LL which are adjacent.

Referring to FIG. 8, a first buffer layer 111a and a second buffer layer 111b may be disposed in the remaining area of the substrate 110 excluding the bending area BA.

The first buffer layer 111a and the second buffer layer 111b may be disposed in the active area AA, the first non-active area NA1, and the second non-active area NA2. The first buffer layer 111a and the second buffer layer 111b may reduce permeation of moisture or impurities through the substrate 110. The first buffer layer 111a and the second buffer layer 111b may be formed of an inorganic insulating material. For example, the first buffer layer 111a and the second buffer layer 111b may include a single layer or multiple layers of silicon oxide (SiOx) or silicon nitride (SiNx), but the exemplary embodiments of the present disclosure are not limited thereto.

For example, the first buffer layer 111a and the second buffer layer 111b on the bending area BA may be partially removed. A top surface of the substrate 110 located in the bending area BA may be exposed from the first buffer layer 111a and the second buffer layer 111b. The first buffer layer 111a and the second buffer layer 111b which are formed of an inorganic insulating material are removed from the bending area BA to minimize or reduce cracks of the first buffer layer 111a and the second buffer layer 111b which may be generated during the bending.

A plurality of alignment keys MK may be disposed between the first buffer layer 111a and the second buffer layer 111b. The plurality of alignment keys MK may be configured to identify a position of the pixel driving circuit PD during the manufacturing process of the display apparatus 1000. For example, the plurality of alignment keys MK may be configured to align a position of the pixel driving circuit PD which is transferred onto the adhesive layer 112. As another example, the plurality of alignment keys MK may be omitted.

The adhesive layer 112 may be disposed on the second buffer layer 111b. The adhesive layer 112 may be disposed in the active area AA, the first non-active area NA1, the bending area BA, and the second non-active area NA2. For example, the adhesive layer 112 may be disposed on the second buffer layer 111b in the active area AA, the first non-active area NA1, and the second non-active area NA2, and on the substrate 110 in the bending area BA, without being limited thereto. As another example, in the non-active area NA including the bending area BA, at least a part of the adhesive layer 112 may be removed. For example, the adhesive layer 112 may be formed of any one of adhesive polymer, epoxy resin, UV curable resin, polyimide based, acrylate based, urethane based, and polydimethylsiloxane (PDMS), but the exemplary embodiments of the present disclosure are not limited thereto.

The pixel driving circuit PD may be disposed on the adhesive layer 112 in the active area AA. When the pixel driving circuit PD is implemented as a driving driver, the driving driver may be mounted on the adhesive layer 112 by the transfer process, but the exemplary embodiments of the present disclosure are not limited thereto.

A first protection layer 113a and a second protection layer 113b may be disposed on the adhesive layer 112 and the pixel driving circuit PD. For example, the first protection layer 113a and the second protection layer 113b may be disposed so as to surround the side surface of the pixel driving circuit PD, but the exemplary embodiments of the present disclosure are not limited thereto. For example, the second protection layer 113b may be disposed so as to cover at least a part of a top surface of the pixel driving circuit PD. For example, at least one of the first protection layer 113a and the second protection layer 113b disposed on the bending area BA may be omitted. For example, the first protection layer 113a may be entirely disposed in the active area AA and the non-active area NA and the second protection layer 113b may be partially disposed in the active area AA, the first non-active area NA1, and the second non-active area NA2. For example, a part of the second protection layer 113b in the bending area BA may be removed, but the exemplary embodiments of the present disclosure are not limited thereto.

The first protection layer 113a and the second protection layer 113b may include an organic insulating material, but the exemplary embodiments of the present disclosure are not limited thereto. For example, the first protection layer 113a and the second protection layer 113b may include a photo resist, polyimide (PI), or photo acrylic material, but the exemplary embodiments of the present disclosure are not limited thereto. For example, the first protection layer 113a and the second protection layer 113b may be over coat layers or insulating layers, but the exemplary embodiments of the present disclosure are not limited thereto.

According to the present disclosure, in the active area AA, the plurality of first connection lines 121 may be disposed on the second protection layer 113b. The plurality of first connection lines 121 may be wiring lines which electrically connect the pixel driving circuit PD to the other component. For example, the pixel driving circuit PD may be electrically connected to the plurality of signal lines TL and the plurality of contact electrodes CCE through the plurality of first connection lines 121. For example, the plurality of first connection lines 121 may include a 1-1-th connection line 121a, a 1-2-th connection line 121b, a 1-3-th connection line 121c, and a 1-4-th connection line 121d, but the exemplary embodiments of the present disclosure are not limited thereto. The connection lines described herein may also be referred to as line connection patterns.

For example, the plurality of 1-1-th connection lines 121a may be disposed on the second protection layer 113b. The plurality of 1-1-th connection lines 121a may be electrically connected to the pixel driving circuit PD. The plurality of 1-1-th connection lines 121a may transmit a voltage output from the pixel driving circuit PD to the first electrode CE1 or the second electrode CE2.

For example, a third protection layer 114 may be disposed on the second protection layer 113b. The third protection layer 114 may be entirely disposed in the active area AA and the non-active area NA. In the bending area BA, the third protection layer 114 may cover a side surface of the second protection layer 113b and the top surface of the first protection layer 113a. The third protection layer 114 may include an organic insulating material. For example, the third protection layer 114 may include a photo resist, polyimide (PI), or photo acrylic material, but the exemplary embodiments of the present disclosure are not limited thereto. For example, the first protection layer 113a, the second protection layer 113b, and the third protection layer 114 may include the same material, but the exemplary embodiments of the present disclosure are not limited thereto.

The plurality of 1-2-th connection lines 121b may be disposed on the third protection layer 114. The plurality of 1-2-th connection lines 121b may be indirectly or directly connected to the pixel driving circuit PD. For example, a part of the 1-2-th connection line 121b may be directly connected to the pixel driving circuit PD through a contact hole of the third protection layer 114. The other part of the 1-2-th connection line 121b may be electrically connected to the 1-1-th connection line 121a through the contact hole of the third protection layer 114, but the exemplary embodiments of the present disclosure are not limited thereto. A voltage output from the pixel driving circuit PD may be transmitted to the first electrode CE1 or the second electrode CE2 through a connection line other than the plurality of 1-2-th connection lines 121b.

The first insulating layer 115a may be disposed on the plurality of 1-2-th connection lines 121b. The first insulating layer 115a may be entirely disposed in the active area AA and the non-active area NA, but the exemplary embodiments of the present disclosure are not limited thereto. The first insulating layer 115a may include an organic insulating material, but the exemplary embodiments of the present disclosure are not limited thereto. For example, the first insulating layer 115a may include a photo resist, polyimide (PI), or photo acrylic material, but the exemplary embodiments of the present disclosure are not limited thereto.

The plurality of 1-3-th connection lines 121c may be disposed on the first insulating layer 115a. The plurality of 1-3-th connection lines 121c may be electrically connected to the plurality of 1-2-th connection lines 121b. For example, the 1-3-th connection lines 121c may be electrically connected to the 1-2-th connection line 121b through a contact hole of the first insulating layer 115a.

The second insulating layer 115b may be disposed on the plurality of 1-3-th connection lines 121c. The second insulating layer 115b may be disposed in a remaining area excluding the bending area BA, but the exemplary embodiments of the present disclosure are not limited thereto. The second insulating layer 115b may be disposed in the active area AA, the first non-active area NA1, and the second non-active area NA2, but the exemplary embodiments of the present disclosure are not limited thereto. For example, a part of the second insulating layer 115b disposed in the bending area BA may be removed. The second insulating layer 115b may include an organic insulating material, but the exemplary embodiments of the present disclosure are not limited thereto. For example, the second insulating layer 115b may include a photo resist, polyimide (PI), or photo acrylic material, but the exemplary embodiments of the present disclosure are not limited thereto.

The plurality of 1-4-th connection lines 121d may be disposed on the second insulating layer 115b. The plurality of 1-4-th connection lines 121d may be electrically connected to the plurality of 1-3-th connection lines 121c. For example, the 1-4-th connection lines 121d may be electrically connected to the 1-3-th connection line 121c through a contact hole of the second insulating layer 115b.

According to the present disclosure, in the non-active area NA, the plurality of second connection lines 122 may be disposed on the second protection layer 113b. The plurality of second connection lines 122 may be wiring lines which transmit a signal transmitted from the flexible circuit board (or flexible film) FCB and the printed circuit board 160 (see FIG. 1) to the pad unit PAD, to the pixel driving circuit PD of the active area AA. For example, the plurality of second connection lines 122 may be electrically connected to the plurality of pad electrodes PE to be applied with a signal from the flexible circuit board (or flexible film) FCB and the printed circuit board.

For example, the plurality of second connection lines 122 extends toward the active area AA from the pad unit PAD to transmit a signal to the wiring line of the active area AA. In this case, the plurality of second connection lines 122 may serve as a link line LL. The plurality of second connection lines 122 may include a 2-1-th connection line 122a, a 2-2-th connection line 122b, a 2-3-th connection line 122c, and a 2-4-th connection line 122d.

The plurality of 2-1-th connection lines 122a may be disposed on the second protection layer 113b. The plurality of 2-1-th connection lines 122a may extend from the second non-active area NA2 to the bending area BA and the first non-active area NA1. The plurality of 2-1-th connection lines 122a may transmit a signal transmitted from the flexible circuit board (or flexible film) FCB and the printed circuit board 160 to the pad unit PAD, to the pixel driving circuit PD of the active area AA.

The plurality of 2-2-th connection lines 122b may be disposed on the third protection layer 114. The plurality of 2-2-th connection lines 122b may be disposed in the second non-active area NA2. The 2-2-th connection line 122b may be electrically connected to the 2-1-th connection line 122a through the contact hole of the third protection layer 114. Accordingly, a signal from the flexible circuit board (or flexible film) FCB and the printed circuit board may be transmitted to the 2-1-th connection line 122a through the 2-2-th connection line 122b.

The 2-3-th connection line 122c may be disposed on the first insulating layer 115a. The 2-3-th connection lines 122c may be disposed in the second non-active area NA2. The 2-3-th connection line 122c may be electrically connected to the 2-2-th connection line 122b through a contact hole of the first insulating layer 115a. Accordingly, a signal from the flexible circuit board (or flexible film) FCB and the printed circuit board may be transmitted to the 2-1-th connection line 122a through the 2-3-th connection line 122c and the 2-2-th connection line 122b.

The 2-4-th connection line 122d may be disposed on the second insulating layer 115b. The 2-4-th connection line 122d may be disposed in the second non-active area NA2. The 2-4-th connection line 122d may be electrically connected to the 2-3-th connection line 122c through a contact hole of the second insulating layer 115b. Accordingly, a signal from the flexible circuit board (or flexible film) FCB and the printed circuit board 160 may be transmitted to the 2-1-th connection line 122a through the 2-4-th connection line 122d, the 2-3-th connection line 122c, and the 2-2-th connection line 122b.

The plurality of first connection lines 121 and the plurality of second connection lines 122 may be formed of any one of a conductive material having excellent ductility or various conductive materials used for the active area AA. For example, the second connection line 122 which is partially disposed in the bending area BA may include a conductive material having excellent ductility, such as gold (Au), silver (Ag), or aluminum (Al), but the exemplary embodiments of the present disclosure are not limited thereto. As another example, the plurality of first connection lines 121 and the plurality of second connection lines 122 may include molybdenum (Mo), chrome (Cr), titanium (Ti), nickel (Ni), neodymium (Nd), copper (Cu), and an alloy of silver (Ag) and magnesium (Mg) or an alloy thereof, but the exemplary embodiments of the present disclosure are not limited thereto.

The third insulating layer 115c may be disposed on the plurality of first connection lines 121 and the plurality of second connection lines 122. The third insulating layer 115c may be disposed in a remaining area excluding the bending area BA, but the exemplary embodiments of the present disclosure are not limited thereto. The third insulating layer 115c may be disposed in the active area AA, the first non-active area NA1, and the second non-active area NA2. A part of the third insulating layer 115c disposed in the bending area BA may be removed. The third insulating layer 115c may include an organic insulating material, but the exemplary embodiments of the present disclosure are not limited thereto. For example, the third insulating layer 115c may include a photo resist, polyimide (PI), or photo acrylic material, but the exemplary embodiments of the present disclosure are not limited thereto.

A plurality of banks BNK may be disposed on the third insulating layer 115c in the active area AA. The plurality of banks BNK may be disposed so as to overlap each of the plurality of sub pixels. One or more same type micro LEDs (ED) may be disposed above each of the plurality of banks BNK.

A plurality of signal lines TL may be disposed on the third insulating layer 115c in the active area AA. The plurality of signal lines TL may be disposed in an area between the plurality of banks BNK. For example, the plurality of signal lines TL may be disposed to be adjacent to any one of the plurality of banks BNK.

A plurality of contact electrodes CCE may be disposed on the third insulating layer 115c in the active area AA. The plurality of contact electrodes CCE may supply a cathode voltage from the pixel driving circuit PD to the second electrode CE2.

The first electrode CE1 may be disposed on the bank BNK. For example, the first electrode CE1 may be disposed to extend toward the top of the bank BNK from the adjacent signal line TL. The first electrode CE1 may be disposed on the top surface of the bank BNK and the side surface of the bank BNK. For example, the first electrode CE1 may be disposed to extend from the signal line TL on the top surface of the third insulating layer 115c to the side surface of the bank BNK and the top surface of the bank BNK.

Referring to FIG. 9, the first electrode CE1 may include a plurality of conductive layers. For example, the first electrode CE1 may include a first conductive layer CE1a, a second conductive layer CE1b, a third conductive layer CE1c, and a fourth conductive layer CE1d, but the exemplary embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may include titanium (Ti), molybdenum (Mo), aluminum (Al), or titanium (Ti) and indium tin oxide (ITO), but the exemplary embodiments of the present disclosure are not limited thereto.

According to the present disclosure, some conductive layers having a good reflection efficiency, among a plurality of conductive layers which configures the first electrode CE1, may be configured as an alignment key for alignment of the micro LED (ED) and/or a reflective plate. For example, the second conductive layer CE1b, among the plurality of conductive layers of the first electrode CE1, may include a reflective material. For example, the second conductive layer CE1b may include aluminum (Al), but the exemplary embodiments of the present disclosure are not limited thereto. Therefore, the second conductive layer CE1b may be configured as a reflective plate. Further, the second conductive layer CE1b has a high reflection efficiency to be easily identified during the manufacturing process so that a position of the micro LED (ED) or a transfer position may be aligned based on the second conductive layer CE1b.

For example, in order to configure the second conductive layer CE1b as a reflective plate, the third conductive layer CE1c and the fourth conductive layer CE1d which cover the second conductive layer CE1b may be partially removed or etched. For example, a part of the third conductive layer CE1c and the fourth conductive layer CE1d disposed on the bank BNK may be removed or etched to expose a top surface of the second conductive layer CE1b. For example, a center portion and an edge portion (or a boundary portion) of the third conductive layer CE1c and the fourth conductive layer CE1d in which a solder pattern SDP is disposed remain and the remaining portion excluding the portions may be removed. For example, an edge portion (or a boundary portion) of each of the third conductive layer CE1c formed of titanium (Ti) and the fourth conductive layer CE1d formed of indium tin oxide (ITO) may not be etched. Therefore, corrosion of another conductive layer of the first electrode CE1 caused by tetramethylammonium hydroxide (TMAH) solution which is used for the mask process of the first electrode CE1 may be suppressed.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which is adhesive to the solder pattern SPD, and has anti-corrosion and acid resistance, but the exemplary embodiments of the present disclosure are not limited thereto.

The first conductive layer CE1a, the second conductive layer CE1b, the third conductive layer CE1c, and the fourth conductive layer CE1d are sequentially deposited, and then are subject to a photolithographic process and an etching process to be patterned. However, the exemplary embodiments of the present disclosure are not limited thereto.

According to the present disclosure, the signal line TL, the contact electrode CCE, and the pad electrode PE disposed on the same layer as the first electrode CE1 may include multiple layers of conductive materials, but the exemplary embodiments of the present disclosure are not limited thereto. For example, the signal line TL, the contact electrode CCE, and the pad electrode PE may be formed of same materials in a same mask process at the same time. For example, the signal line TL, the contact electrode CCE, and the pad electrode PE may be formed of multiple layers of indium tin oxide (ITO)/titanium (Ti)/aluminum (Al)/titanium (Ti), but the exemplary embodiments of the present disclosure are not limited thereto.

According to the present disclosure, in each of the plurality of sub pixels, a solder pattern SDP may be disposed on the first electrode CE1. The solder pattern SDP bonds the micro LED (ED) to the first electrode CE1 to electrically connect the first electrode CE1 and the micro LED (ED). For example, the first electrode CE1 and the anode electrode 134 of the micro LED (ED) may be electrically connected through eutectic bonding using the solder pattern SDP, but the exemplary embodiments of the present disclosure are not limited thereto.

For example, when the solder pattern SDP is configured by indium (In) and the anode electrode 134 of the micro LED (ED) is configured by gold (Au), during the transfer process of the micro LED (ED), heat and pressure are applied to bond the solder pattern SDP and the anode electrode 134. The micro LED (ED) may be bonded to the solder pattern SDP and the first electrode CE1 using the eutectic bonding without a separate adhesive material. For example, the solder pattern SDP may include indium (Id), tin (Sn), or an alloy thereof, but the exemplary embodiments of the present disclosure are not limited thereto. For example, the solder pattern SDP may be a bonding pad or an adhesive pad, but the exemplary embodiments of the present disclosure are not limited thereto.

According to the present disclosure, the passivation layer 116 may be disposed on the plurality of signal lines TL, the plurality of first electrodes CE1, the plurality of contact electrodes CCE, and the third insulating layer 115c. For example, the passivation layer 116 may be disposed in the active area AA, the first non-active area NA1, and the second non-active area NA2. A part of the passivation layer 116 disposed in the bending area BA may be removed. A part of the passivation layer 116 which covers a plurality of pad electrodes PE in the second non-active area NA2 may be removed. The passivation layer 116 is disposed so as to cover the remaining area excluding the bending area BA, the plurality of pad electrodes PE, and the solder pattern SDP to reduce permeation of moisture or impurities entering the micro LED (ED). For example, the passivation layer 116 may include a single layer or multiple layers of silicon oxide (SiOx) or silicon nitride (SiNx), but the exemplary embodiments of the present disclosure are not limited thereto. For example, the passivation layer 116 may be a protection layer or an insulating layer, but the exemplary embodiments of the present disclosure are not limited thereto. For example, the passivation layer 116 may include a hole through which the solder pattern SDP is exposed.

In each of the plurality of sub pixels, the micro LED (ED) may be disposed on the solder pattern SDP. A first micro LED 130 may be disposed in the first sub pixel SP1. A second micro LED 140 may be disposed in the second sub pixel SP2. A third micro LED 150 may be disposed in the third sub pixel SP3.

The micro LED (ED) may be formed on a silicon wafer using metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or a sputtering method. However, the exemplary embodiments of the present disclosure are not limited thereto.

Referring to FIG. 9, the first micro LED 130 may include an anode electrode 134, a first semiconductor layer 131, an active layer 132, a second semiconductor layer 133, a cathode electrode 135, and an encapsulation film 136, but the exemplary embodiments of the present disclosure are not limited thereto. For example, the encapsulation film 136 may not be included in the first micro LED 130.

The first semiconductor layer 131 may be disposed on the solder pattern SDP. The second semiconductor layer 133 may be disposed on the first semiconductor layer 131. For example, the active layer 132 may be disposed on the first semiconductor layer 131, and the second semiconductor layer 133 may be disposed on the active layer 132.

For example, one of the first semiconductor layer 131 and the second semiconductor layer 133 may be implemented by a compound semiconductor, such as a III-V group or a II-VI group and may be doped with an impurity (or dopant). For example, one of the first semiconductor layer 131 and the second semiconductor layer 133 may be an n-type impurity-doped semiconductor layer and the other one may be a p-type impurity-doped semiconductor layer, but the exemplary embodiments of the present disclosure are not limited thereto. For example, one or more of the first semiconductor layer 131 and the second semiconductor layer 133 may be a layer in which n-type or p-type impurity is doped on a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the exemplary embodiments of the present disclosure are not limited thereto. For example, the n-type impurity may be silicon (Si), germanium (Ge), selenium (Se), carbon (C), tellurium (Te), or tin (Sn), but the exemplary embodiments of the present disclosure are not limited thereto. For example, the p-type impurity may be magnesium (Mg), zinc (Zn), calcium (Ca), strontium (Sr), barium (Ba), or beryllium (Be), but the exemplary embodiments of the present disclosure are not limited thereto.

For example, each of the first semiconductor layer 131 and the second semiconductor layer 133 may be a nitride semiconductor including an n-type impurity or a nitride semiconductor including a p-type impurity, but the exemplary embodiments of the present disclosure are not limited thereto. For example, the first semiconductor layer 131 may be a nitride semiconductor including a p-type impurity and the second semiconductor layer 133 may be a nitride semiconductor including an n-type impurity, but the exemplary embodiments of the present disclosure are not limited thereto.

The active layer 132 may be disposed between the first semiconductor layer 131 and the second semiconductor layer 133. The active layer 132 is supplied with holes and electrons from the first semiconductor layer 131 and the second semiconductor layer 133 to emit light. For example, the active layer 132 may include a single well structure, a multi-well structure, a signal quantum well structure, a multi-quantum well (MQW) structure, a quantum dot structure, and a quantum line structure, but the exemplary embodiments of the present disclosure are not limited thereto. For example, the active layer 132 may include indium gallium nitride (InGaN) or gallium nitride (GaN), but the exemplary embodiments of the present disclosure are not limited thereto.

As another example, the active layer 132 may have a multi quantum well (MQW) structure having a well layer and a barrier layer with a band gap higher than the well layer. For example, in the active layer 132, InGaN may be configured as a well layer and an AlGaN layer may be configured as a barrier layer, but the exemplary embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may include a conductive material which may form eutectic bonding with the solder pattern SDP, but the exemplary embodiments of the present disclosure are not limited thereto. For example, the anode electrode 134 may include gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the exemplary embodiments of the present disclosure are not limited thereto.

The cathode electrode 135 may be disposed on the second semiconductor layer 133. For example, the cathode electrode 135 may electrically connect the second semiconductor layer 133 and the second electrode CE2. A cathode voltage output from the pixel driving circuit PD may be applied to the second semiconductor layer 133 through the contact electrode CCE, the second electrode CE2, and the cathode electrode 135. The cathode electrode 135 may include a transparent conductive material to allow light emitted from the micro LED (ED) to be directed to the top of the micro LED (ED), but the exemplary embodiments of the present disclosure are not limited thereto. For example, the cathode electrode 135 may include a material, such as indium tin oxide (ITO), indium zinc oxide (IZO), or indium gallium zinc oxide (IGZO), but the exemplary embodiments of the present disclosure are not limited thereto.

The encapsulation film 136 may be disposed in at least a part of the first semiconductor layer 131, the active layer 132, the second semiconductor layer 133, the anode electrode 134, and the cathode electrode 135. For example, the encapsulation film 136 may surround at least a part of the first semiconductor layer 131, the active layer 132, the second semiconductor layer 133, the anode electrode 134, and the cathode electrode 135, without being limited thereto. For example, the encapsulation film 136 may not be included in the micro LED (ED).

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least a part of the anode electrode 134 and the cathode electrode 135, for example, on an edge portion (or a boundary portion or one side) of the anode electrode 134 and an edge portion (or a boundary portion or one side) of the cathode electrode 135. At least a part of the anode electrode 134 is exposed from the encapsulation film 136 so that the anode electrode 134 and the solder pattern SDP may be connected. For example, at least a part of the cathode electrode 135 is exposed from the encapsulation film 136 so that the cathode electrode 135 and the second electrode CE2 may be connected. For example, the encapsulation film 136 may be formed of an insulating material, such as silicon nitride (SiNx) or silicon oxide (SiOx), but the exemplary embodiments of the present disclosure are not limited thereto.

As another example, the encapsulation film 136 may have a structure in which a reflective material is dispersed in a resin layer, but the exemplary embodiments of the present disclosure are not limited thereto. For example, the encapsulation film 136 may be manufactured with reflectors with various structures, but the exemplary embodiments of the present disclosure are not limited thereto. Light emitted from the active layer 132 is upwardly reflected by the encapsulation film 136 so that light extraction efficiency may be improved. For example, the encapsulation film 136 may be a reflective layer, but the exemplary embodiments of the present disclosure are not limited thereto.

According to the present disclosure, it is described that the micro LED (ED) has a vertical structure, but the exemplary embodiments of the present disclosure are not limited thereto. For example, the micro LED (ED) may have a lateral structure or a flip-chip structure.

The first micro LED 130 has been described with reference to FIG. 9 and the second micro LED 140 and the third micro LED 150 may have substantially the same structure as the first micro LED 130. For example, the second micro LED 140 and the third micro LED 150 may be substantially the same as the first semiconductor layer 131, the active layer 132, the second semiconductor layer 133, the anode electrode 134, the cathode electrode 135, and the encapsulation film 136 of the first micro LED 130.

According to the present disclosure, in the active area AA, a first optical layer 117a which surrounds the plurality of micro LEDs (ED) may be disposed. For example, the first optical layer 117a may be disposed so as to cover the plurality of micro LEDs (ED) and the bank BNK in the area of the plurality of sub pixels. For example, the first optical layer 117a may cover the bank BNK, a part of the passivation layer 116 and between the plurality of micro LEDs (ED). The first optical layer 117a may be disposed or cover between the plurality of micro LEDs (ED) and between the plurality of banks BNK included in one pixel PX. For example, the first optical layer 117a extends in a first row direction and may be disposed to be spaced apart from each other in a second column direction. For example, the first optical layer 117a may be arranged between the passivation layer 116 and the second electrode CE2, but the embodiments of the present disclosure are not limited thereto. For example, the first optical layer 117a may be disposed so as to surround side portions of the micro LED (ED) and the bank BNK between the passivation layer 116 and the second electrode CE2, but the exemplary embodiments of the present disclosure are not limited thereto. For example, the first optical layer 117a may be a diffusion layer or a side wall diffusion layer, but the exemplary embodiments of the present disclosure are not limited thereto.

The first optical layer 117a may include an organic insulating material in which micro particles are dispersed, but the exemplary embodiments of the present disclosure are not limited thereto. For example, the first optical layer 117a may include siloxane in which micro metal particles, such as titanium dioxide (TiO₂) particles, are dispersed, but the exemplary embodiments of the present disclosure are not limited thereto. Light from the plurality of micro LEDs (ED) is scattered by micro particles dispersed in the first optical layer 117a to be emitted to the outside of the display apparatus 1000. Accordingly, the first optical layer 117a may improve extraction efficiency of light emitted from the plurality of micro LEDs (ED).

For example, the first optical layer 117a may be disposed in each of the plurality of pixels PX or disposed in some pixels PX disposed in the same row together, but the exemplary embodiments of the present disclosure are not limited thereto. For example, the first optical layer 117a may be disposed in each of the plurality of pixels PX or the plurality of pixels PX may share one first optical layer 117a. As another example, each of the plurality of sub pixels may separately include the first optical layer 117a, but the exemplary embodiments of the present disclosure are not limited thereto.

According to the present disclosure, in the active area AA, a second optical layer 117b may be disposed on the passivation layer 116. For example, the second optical layer 117b may be disposed so as to surround the first optical layer 117a. For example, the second optical layer 117b may be in contact with a side surface of the first optical layer 117a. For example, the second optical layer 117b may be disposed in an area between the plurality of pixels PX. However, the exemplary embodiments of the present disclosure are not limited thereto. For example, the second optical layer 117b may be a diffusion layer, a diffusion layer window, or a window diffusion layer, but the exemplary embodiments of the present disclosure are not limited thereto.

The second optical layer 117b may include an organic insulating material, but the exemplary embodiments of the present disclosure are not limited thereto. The second optical layer 117b may include the same material as the first optical layer 117a, but the exemplary embodiments of the present disclosure are not limited thereto. For example, the first optical layer 117a may include micro particles, but the second optical layer 117b may not include micro particles. For example, the second optical layer 117b may include siloxane, but the exemplary embodiments of the present disclosure are not limited thereto.

For example, a thickness of the first optical layer 117a may be smaller than a thickness of the second optical layer 117b, but the exemplary embodiments of the present disclosure are not limited thereto. Accordingly, in the plan view, an area in which the first optical layer 117a is disposed may include a concave portion which is inwardly dented from an upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE through a contact hole of the second optical layer 117b. For example, the second electrode CE2 may be disposed on the plurality of micro LEDs (ED). For example, the second electrode CE2 may include a transparent conductive oxide, such as indium tin oxide (ITO) or indium zinc oxide (IZO), but the exemplary embodiments of the present disclosure are not limited thereto. For example, the second electrode CE2 may be disposed to be in contact with the cathode electrode 135. For example, the second electrode CE2 may overlap the first optical layer 117a. For example, the second electrode may cover a plane of the outside of the first optical layer 117a.

The second electrode CE2 may continuously extend in a first direction of the substrate 110. Accordingly, the second electrode CE2 may be commonly connected to the plurality of pixels PX disposed in the first direction of the substrate 110. For example, the second electrode CE2 may be commonly connected to the plurality of pixels PX.

According to the present disclosure, the second electrode CE2 may continuously extend on the first optical layer 117a, the second optical layer 117b, and the micro LED (ED). The area in which the first optical layer 117a is disposed may include a concave portion which is inwardly dented from an upper surface of the second optical layer 117b. Accordingly, the first part of the second electrode CE2 disposed on the first optical layer 117a is disposed along the concave portion so that the first part may be disposed to be lower than the second part of the second electrode CE2 disposed on the second optical layer 117b.

The third optical layer 117c may be disposed on the second electrode CE2. The third optical layer 117c may be disposed so as to overlap the plurality of micro LEDs (ED) and the first optical layer 117a. The third optical layer 117c is disposed above the second electrode CE2 and the plurality of micro LEDs (ED) so that mura which may be generated in a part of the plurality of micro LEDs (ED) may be improved. For example, when the plurality of micro LEDs (ED) is transferred onto the substrate 110 of the display apparatus 1000, an area in which the interval between the plurality of micro LEDs (ED) is not uniform may be caused due to a process deviation. When the interval between the plurality of micro LEDs (ED) is not uniform, an emission area of each of the plurality of micro LEDs (ED) may not uniformly disposed so that the mura may be visible to a user. Accordingly, the third optical layer 117c which is configured to uniformly diffuse light is configured above the plurality of micro LEDs (ED) so that light emitted from some micro LEDs (ED) which is visible as mura may be reduced. Accordingly, light emitted from the plurality of micro LEDs (ED) is uniformly diffused by the third optical layer 117c to be extracted to the outside of the display apparatus 1000 so that the luminance uniformity of the display apparatus 1000 may be improved.

The third optical layer 117c may be formed of the same material as the first optical layer 117a, but the embodiments of the present disclosure are not limited thereto. The third optical layer 117c may include an organic insulating material in which micro particles are dispersed, but the exemplary embodiments of the present disclosure are not limited thereto. For example, the third optical layer 117c may include siloxane in which micro metal particles, such as titanium dioxide (TiO₂) particles, are dispersed, but the exemplary embodiments of the present disclosure are not limited thereto. For example, the third optical layer 117c may include the same material as the first optical layer 117a, but the exemplary embodiments of the present disclosure are not limited thereto. For example, the third optical layer 117c may be a diffusion layer or a top surface diffusion layer, but the exemplary embodiments of the present disclosure are not limited thereto.

According to the present disclosure, light from the plurality of micro LEDs (ED) is scattered by micro particles dispersed in the third optical layer 117c to be emitted to the outside of the display apparatus 1000. The third optical layer 117c uniformly mixes light emitted from the plurality of micro LEDs (ED) to further improve the luminance uniformity of the display apparatus 1000. The light extraction efficiency of the display apparatus 1000 may be improved by light scattered from the plurality of micro particles so that the display apparatus 1000 may be driven at a low power.

In the active area AA, a black matrix BM may be disposed on the second electrode CE2, the first optical layer 117a, the second optical layer 117b, and the third optical layer 117c. For example, the contact hole of the second optical layer 117b may be filled with the black matrix BM. The black matrix BM is configured to cover the active area AA to reduce color mixture and external light reflection of light of the plurality of sub pixels. For example, the black matrix BM is disposed in the contact hole through which the second electrode CE2 and the contact electrode CCE are connected so that light leakage between the plurality of adjacent sub pixels may be suppressed.

For example, the black matrix BM may include an opaque material, but the exemplary embodiments of the present disclosure are not limited thereto. For example, the black matrix BM may include an organic insulating material to which black pigment or black dye is added, but the exemplary embodiments of the present disclosure are not limited thereto.

In the active area AA, a cover layer 118 may be disposed on the black matrix BM. The cover layer 118 may protect configurations below the cover layer 118. For example, the cover layer 118 may include an organic insulating material, but the exemplary embodiments of the present disclosure are not limited thereto. For example, the cover layer 118 may include a photo resist, polyimide (PI), or photo acrylic material, but the exemplary embodiments of the present disclosure are not limited thereto. For example, the cover layer 118 may be an over coat layer or an insulating layer, but the exemplary embodiments of the present disclosure are not limited thereto.

A polarization layer 293 may be disposed on the cover layer 118 by means of the first adhesive layer 291. A cover member 120 may be disposed on the polarization layer 293 by means of the second adhesive layer 295. For example, the first adhesive layer 291 and the second adhesive layer 295 may include an optically clear adhesive (OCA), an optically clear resin (OCR), or a pressure sensitive adhesive (PSA), but the exemplary embodiments of the present disclosure are not limited thereto.

According to the present disclosure, a plurality of pad electrodes PE may be disposed on the third insulating layer 115c in the second non-active area NA2. For example, at least some of the plurality of pad electrodes PE may be exposed from the passivation layer 116. For example, the plurality of pad electrodes PE may be electrically connected to the 2-4-th connection line 122d through a contact hole of the third insulating layer 115c.

The adhesive layer ACF may be disposed on the plurality of pad electrodes PE. The adhesive layer ACF may be an adhesive layer in which conductive balls are dispersed in an insulating material, but the exemplary embodiments of the present disclosure are not limited thereto. When heat or pressure is applied to the adhesive layer ACF, the conductive balls are electrically connected in a portion applied with the heat or pressure to have a conductive property. The adhesive layer ACF is disposed between the plurality of pad electrodes PE and the flexible circuit board (or flexible film) FCB, and the flexible circuit board (or flexible film) FCB may be attached or bonded to the plurality of pad electrodes PE. For example, the adhesive layer ACF may be anisotropic conductive film, but the exemplary embodiments of the present disclosure are not limited thereto.

The flexible circuit board (or flexible film) FCB may be disposed on the adhesive layer ACF. The flexible circuit board (or flexible film) FCB may be electrically connected to the plurality of pad electrodes PE through the adhesive layer ACF. Accordingly, a signal output from the flexible circuit board (or flexible film) FCB and the printed circuit board 160 may be transmitted to the pixel driving circuit PD of the active area AA through the plurality of pad electrodes PE, the 2-4-th connection line 122d, the 2-3-th connection line 122c, the 2-2-th connection line 122b, and the 2-1-th connection line 122a.

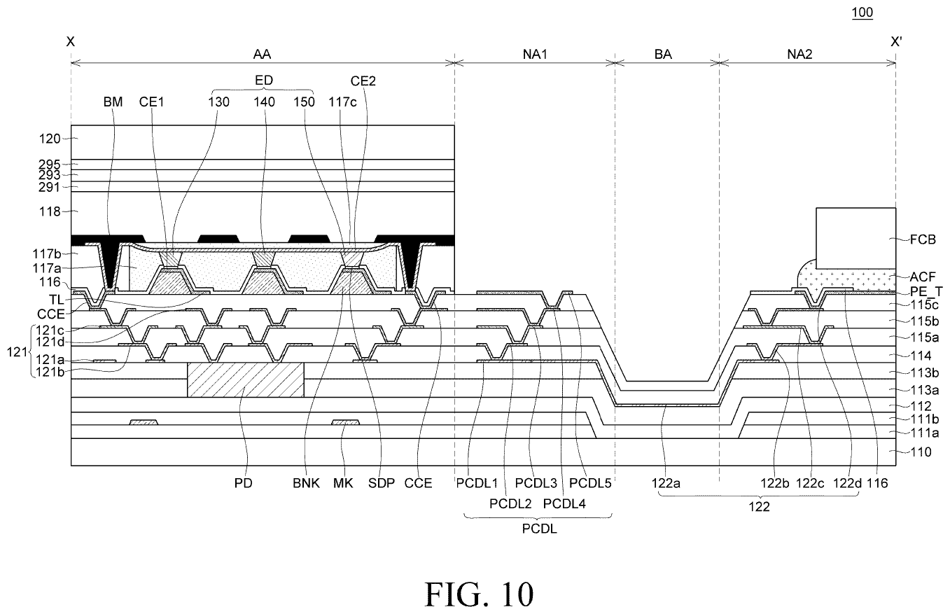

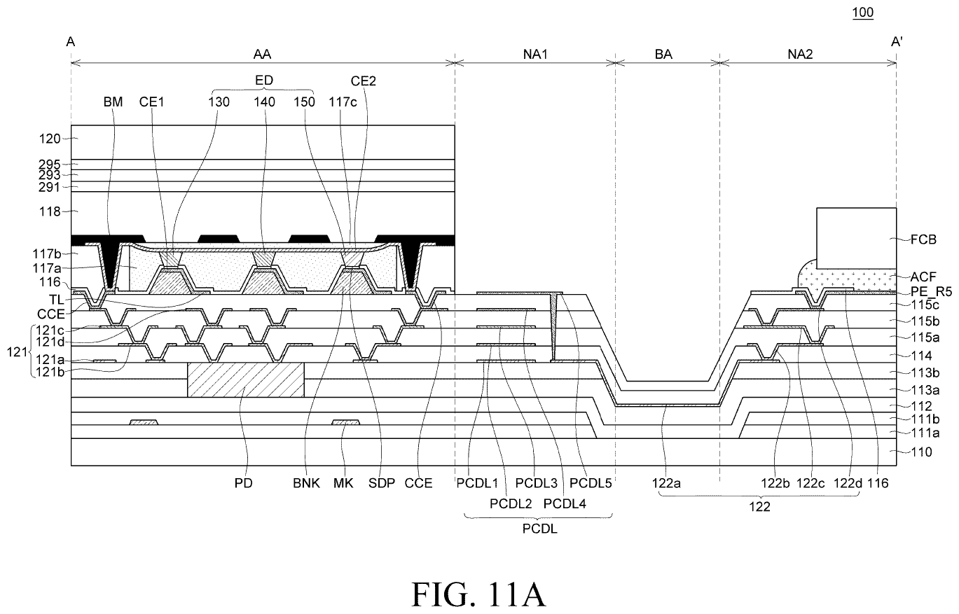

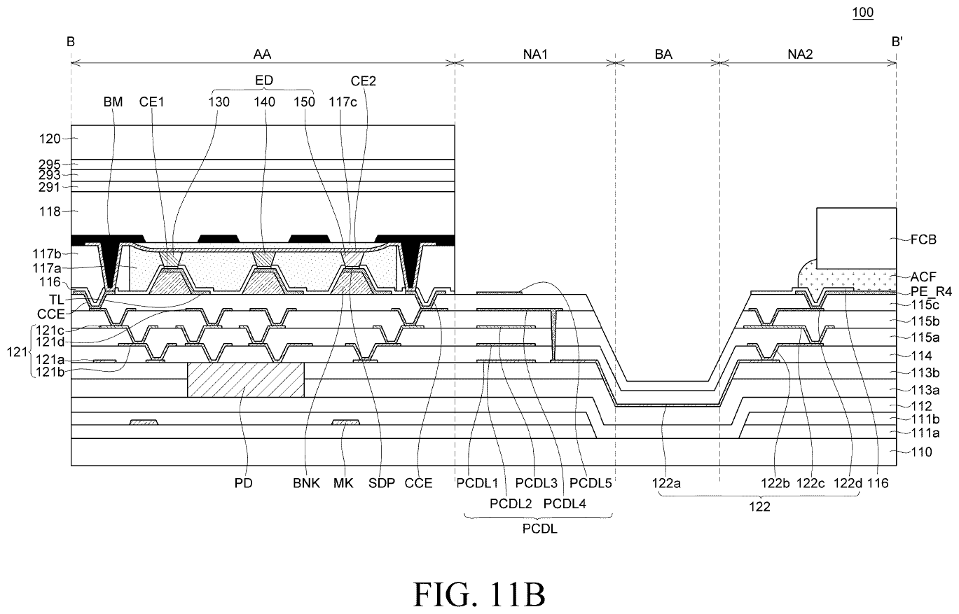

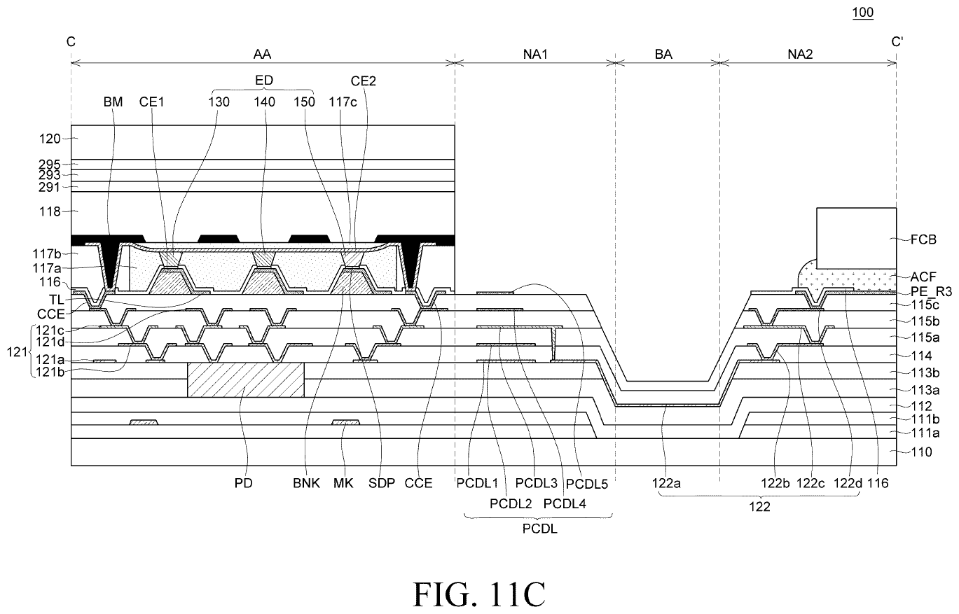

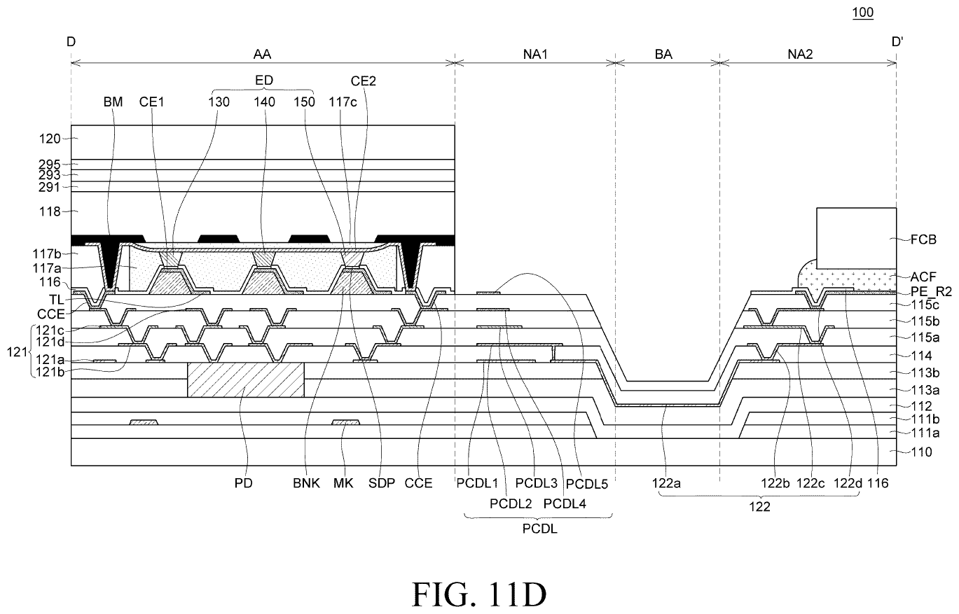

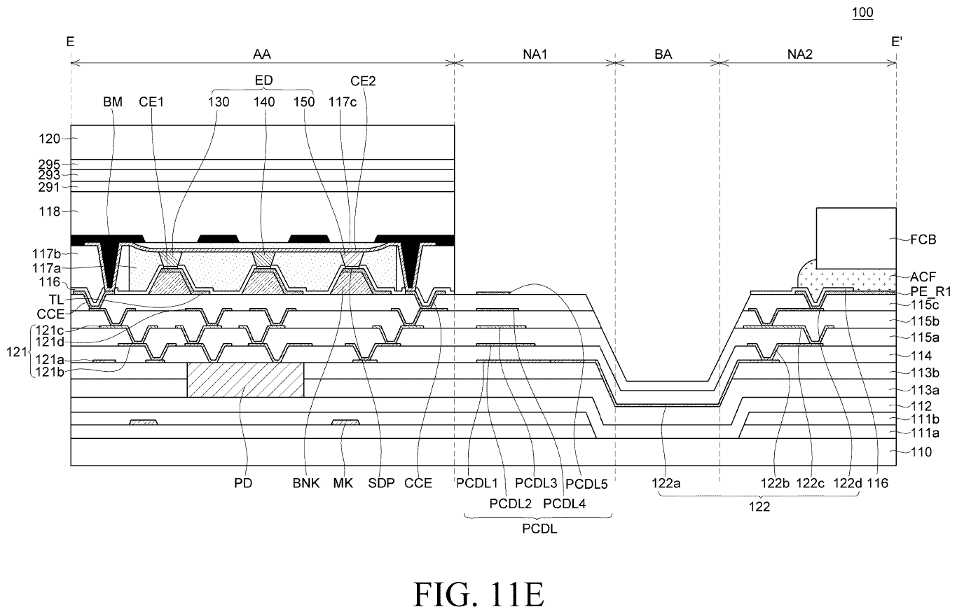

FIG. 10 is a cross-sectional view taken along the line X-X′ of FIG. 2A. FIG. 11A is a cross-sectional view taken along the line A-A′ of FIG. 2A. FIG. 11B is a cross-sectional view taken along the line B-B′ of FIG. 2A. FIG. 11C is a cross-sectional view taken along the line C-C′ of FIG. 2A. FIG. 11D is a cross-sectional view taken along D-D′ of FIG. 2A. FIG. 11E is a cross-sectional view taken along E-E′ of FIG. 2A. Specifically, FIG. 10 is a cross-sectional view illustrating a connection structure of a plurality of crack detection lines PCDL and a signal transmission pad electrode PE_T. FIGS. 11A to 11E are cross-sectional views illustrating a connection structure of a plurality of crack detection lines PCDL and a plurality of signal reception pad electrodes PE_R. In addition, for the convenience of illustration, in FIGS. 10 to 11E, it is illustrated that a cross-sectional line and the plurality of crack detection lines PCDL and a link line LL do not overlap. The cross-sectional line of FIGS. 10 to 11E is provided to represent the same position as the plurality of crack detection lines PCDL and link line LL which are adjacent.

Referring to FIGS. 10 to 11E, the plurality of crack detection lines PCDL may be disposed on the second protection layer 113b. The plurality of crack detection lines PCDL may include a first crack detection line PCDL1, a second crack detection line PCDL2, a third crack detection line PCDL3, a fourth crack detection line PCDL4, and a fifth crack detection line PCDL5 which are disposed on different layers.

For example, the first crack detection line PCDL1 may be disposed on the second protection layer 113b. The first crack detection line PCDL1 is disposed on the same layer as the plurality of 1-1-th connection lines 121a and the plurality of 2-1-th connection lines 122a to be formed of the same material, but is not limited thereto.

Referring to FIGS. 10 and 11E, one end of the first crack detection line PCDL1 may be electrically connected to the signal transmission pad electrode PE_T and the other end of the first crack detection line PCDL1 may be connected to the first signal reception pad electrode PE_R1.

For example, referring to FIG. 10, one end of the first crack detection line PCDL1 may be connected to the signal transmission pad electrode PE_T through the second connection line 122 and may be electrically connected to the flexible circuit board FCB through the signal transmission pad electrode PE_T. Therefore, one end of the first crack detection line PCDL1 may receive a crack detection signal from the flexible circuit board FCB through the signal transmission pad electrode PE_T.

Referring to FIG. 11E, the other end of the first crack detection line PCDL1 may be connected to the first signal reception pad electrode PE_R1 through the second connection line 122 and may be electrically connected to the flexible circuit board FCB through the first signal reception pad electrode PE_R1. Therefore, the first crack detection line PCDL1 may transmit the crack detection signal to the flexible circuit board FCB through the first signal reception pad electrode PE_R1.

Referring to FIGS. 10 to 11E, the second crack detection line PCDL2 may be disposed on the third protection layer 114. The second crack detection line PCDL2 is disposed on the same layer as the plurality of 1-2-th connection lines 121b and the plurality of 2-2-th connection lines 122b to be formed of the same material, but is not limited thereto.

Referring to FIGS. 10 and 11D, one end of the second crack detection line PCDL2 may be electrically connected to the signal transmission pad electrode PE_T and the other end of the second crack detection line PCDL2 may be connected to the second signal reception pad electrode PE_R2.

For example, referring to FIG. 10, one end of the second crack detection line PCDL2 may be connected to the signal transmission pad electrode PE_T through the second connection line 122 and may be electrically connected to the flexible circuit board FCB through the signal transmission pad electrode PE_T. Therefore, the second crack detection line PCDL2 may receive a crack detection signal from the flexible circuit board FCB through the signal transmission pad electrode PE_T.

In addition, the second crack detection line PCDL2 may be connected to the same signal transmission pad electrode PE_T as the first crack detection line PCDL1. Therefore, one end of the second crack detection line PCDL2 is connected to the first crack detection line PCDL1 through a contact hole of the third protection layer 114 to be electrically connected to the signal transmission pad electrode PE_T through the first crack detection line PCDL1. For example, the second crack detection line PCDL2 may be connected to the second connection line 122 through the first crack detection line PCDL1 and may be connected to the signal transmission pad electrode PE_T through the second connection line 122. Therefore, the second crack detection line PCDL2 is electrically connected to the flexible circuit board FCB through the signal transmission pad electrode PE_T to receive a crack detection signal from the flexible circuit board FCB.

For example, the second connection line 122 which is connected to the signal transmission pad electrode PE_T may electrically connect both the first crack detection line PCDL1 and the second crack detection line PCDL2 to the signal transmission pad electrode PE_T.

Referring to FIG. 11D, the other end of the second crack detection line PCDL2 may be connected to the second connection line 122 through a contact hole of the second protection layer 113b and may be connected to the second signal reception pad electrode PE_R2 through the second connection line 122. Further, the other end of the second crack detection line PCDL2 may be electrically connected to the flexible circuit board FCB through the second signal reception pad electrode PE_R2. Therefore, the second crack detection line PCDL2 may transmit the crack detection signal to the flexible circuit board FCB through the second signal reception pad electrode PE_R2.

In addition, the second connection line 122 which connects the second crack detection line PCDL2 and the second signal reception pad electrode PE_R2 may be different from the second connection line which connects the first crack detection line PCDL1 and the first signal reception pad electrode PE_R1.

Referring to FIGS. 10 to 11E, the third crack detection line PCDL3 may be disposed on the first insulating layer 115a. The third crack detection line PCDL3 is disposed on the same layer as the plurality of 1-3-th connection lines 121c and the plurality of 2-3-th connection lines 122c to be formed of the same material, but is not limited thereto.

Referring to FIGS. 10 and 11C, one end of the third crack detection line PCDL3 may be electrically connected to the signal transmission pad electrode PE_T and the other end of the third crack detection line PCDL3 may be connected to the third signal reception pad electrode PE_R3.

For example, referring to FIG. 10, one end of the third crack detection line PCDL3 may be connected to the signal transmission pad electrode PE_T through the second connection line 122 and may be electrically connected to the flexible circuit board FCB through the signal transmission pad electrode PE_T. Therefore, the third crack detection line may receive a crack detection signal from the flexible circuit board FCB.

In addition, the third crack detection line PCDL3 may be connected to the same signal transmission pad electrode PE_T as the first crack detection line PCDL1 and the second crack detection line PCDL2. Therefore, one end of the third crack detection line PCDL3 is connected to the second crack detection line PCDL2 through a contact hole of the first insulating layer 115a to be electrically connected to the signal transmission pad electrode PE_T through the second crack detection line PCDL2. For example, the third crack detection line PCDL3 may be connected to the first crack detection line PCDL1 through the second crack detection line PCDL2 and may be connected to the second connection line 122 through the first crack detection line PCDL1. Accordingly, the third crack detection line PCDL3 may be connected to the signal transmission pad electrode PE_T through the second connection line 122 and may be electrically connected to the flexible circuit board FCB through the signal transmission pad electrode PE_T to receive a crack detection signal from the flexible circuit board FCB.

For example, the second connection line 122 which is connected to the signal transmission pad electrode PE_T may electrically connect all the first crack detection line PCDL1, the second crack detection line PCDL2, and the third crack detection line PCDL3 to the signal transmission pad electrode PE_T.

Referring to FIG. 11C, the other end of the third crack detection line PCDL3 may be connected to the third signal reception pad electrode PE_R3 through the second connection line 122 and may be electrically connected to the flexible circuit board FCB through the third signal reception pad electrode PE_R3. Therefore, the third crack detection line PCDL3 may transmit the crack detection signal to the flexible circuit board FCB through the third signal reception pad electrode PE_R3.

In addition, the second connection line 122 which connects the third crack detection line PCDL3 and the third signal reception pad electrode PE_R3 may be different from the second connection line which connects the first crack detection line PCDL1 and the first signal reception pad electrode PE_R1 and the second connection line which connects the second crack detection line PCDL2 and the second signal reception pad electrode PE_R2.

Referring to FIGS. 10 to 11E, the fourth crack detection line PCDL4 may be disposed on the second insulating layer 115b. The fourth crack detection line PCDL4 is disposed on the same layer as the plurality of 1-4-th connection lines 121d and the plurality of 2-4-th connection lines 122d to be formed of the same material, but is not limited thereto.

Referring to FIGS. 10 and 11B, one end of the fourth crack detection line PCDL4 may be electrically connected to the signal transmission pad electrode PE_T and the other end of the fourth crack detection line PCDL4 may be connected to the fourth signal reception pad electrode PE_R4.

For example, referring to FIG. 10, one end of the fourth crack detection line PCDL4 may be connected to the signal transmission pad electrode PE_T through the second connection line 122 and may be electrically connected to the flexible circuit board FCB through the signal transmission pad electrode PE_T. Therefore, the fourth crack detection line PCDL4 may receive a crack detection signal from the flexible circuit board FCB.

In addition, the fourth crack detection line PCDL4 may be connected to the same signal transmission pad electrode PE_T as the first crack detection line PCDL1, the second crack detection line PCDL2, and the third crack detection line PCDL3. Therefore, one end of the fourth crack detection line PCDL4 is connected to the third crack detection line PCDL3 through a contact hole of the second insulating layer 115b to be electrically connected to the signal transmission pad electrode PE_T through the third crack detection line PCDL3. For example, the fourth crack detection line PCDL4 may be connected to the second crack detection line PCDL2 through the third crack detection line PCDL3, may be connected to the first crack detection line PCDL1 through the second crack detection line PCDL2, and may be connected to the second connection line 122 through the first crack detection line PCDL1. Accordingly, the fourth crack detection line PCDL4 may be connected to the signal transmission pad electrode PE_T through the second connection line 122 and may be electrically connected to the flexible circuit board FCB through the signal transmission pad electrode PE_T to receive a crack detection signal from the flexible circuit board FCB.

For example, the second connection line 122 which is connected to the signal transmission pad electrode PE_T may electrically connect all the first crack detection line PCDL1, the second crack detection line PCDL2, the third crack detection line PCDL3, and the fourth crack detection line PCDL4 to the signal transmission pad electrode PE_T.

Referring to FIG. 11B, the other end of the fourth crack detection line PCDL4 may be connected to the fourth signal reception pad electrode PE_R4 through the second connection line 122 and may be electrically connected to the flexible circuit board FCB through the fourth signal reception pad electrode PE_R4. Therefore, the fourth crack detection line PCDL4 may transmit the crack detection signal to the flexible circuit board FCB through the fourth signal reception pad electrode PE_R4.

In addition, the second connection line 122 which connects the fourth crack detection line PCDL4 and the fourth signal reception pad electrode PE_R4 may be different from the second connection line 122 which connects the first crack detection line PCDL1 and the first signal reception pad electrode PE_R1, the second connection line 122 which connects the second crack detection line PCDL2 and the second signal reception pad electrode PE_R2, and the second connection line 122 which connects the third crack detection line PCDL3 and the third signal reception pad electrode PE_R3.

Referring to FIGS. 10 to 11E, the fifth crack detection line PCDL5 may be disposed on the third insulating layer 115c. The fifth crack detection line PCDL5 is disposed on the same layer as the plurality of signal lines TL and the plurality of pad electrodes PE to be formed of the same material, but is not limited thereto.

Referring to FIGS. 10 and 11A, one end of the fifth crack detection line PCDL5 may be electrically connected to the signal transmission pad electrode PE_T and the other end of the fifth crack detection line PCDL5 may be connected to the fifth signal reception pad electrode PE_R5.

For example, referring to FIG. 10, one end of the fifth crack detection line PCDL5 may be connected to the signal transmission pad electrode PE_T through the second connection line 122 and may be electrically connected to the flexible circuit board FCB through the signal transmission pad electrode PE_T. Therefore, the fifth crack detection line PCDL5 may receive a crack detection signal from the flexible circuit board FCB.

In addition, the fifth crack detection line PCDL5 may be connected to the same signal transmission pad electrode PE_T as the first crack detection line PCDL1, the second crack detection line PCDL2, the third crack detection line PCDL3, and the fourth crack detection line PCDL4. Therefore, one end of the fourth crack detection line PCDL4 is connected to the fourth crack detection line PCDL4 through a contact hole of the third insulating layer 115c to be electrically connected to the signal transmission pad electrode PE_T through the fourth crack detection line PCDL4. For example, the fifth crack detection line PCDL5 may be connected to the third crack detection line PCDL3 through the fourth crack detection line PCDL4 and may be connected to the second crack detection line PCDL2 through the third crack detection line PCDL3. The fifth crack detection line PCDL5 may be connected to the first crack detection line PCDL1 through the second crack detection line PCDL2 and may be connected to the second connection line 122 through the first crack detection line PCDL1. Accordingly, the fifth crack detection line PCDL5 is connected to the signal transmission pad electrode PE_T through the second connection line 122 and is electrically connected to the flexible circuit board FCB through the signal transmission pad electrode PE_T to receive a crack detection signal from the flexible circuit board FCB.

For example, the second connection line 122 which is connected to the signal transmission pad electrode PE_T may electrically connect all the first crack detection line PCDL1, the second crack detection line PCDL2, the third crack detection line PCDL3, the fourth crack detection line PCDL4, and the fifth crack detection line PCDL5 to the signal transmission pad electrode PE_T.

Referring to FIG. 11A, the other end of the fifth crack detection line PCDL5 may be connected to the fifth signal reception pad electrode PE_R5 through the second connection line 122 and may be electrically connected to the flexible circuit board FCB through the fifth signal reception pad electrode PE_R5. Therefore, the fifth crack detection line PCDL5 may transmits the crack detection signal to the flexible circuit board FCB through the fifth signal reception pad electrode PE_R5.

In addition, the second connection line 122 which connects the fifth crack detection line PCDL5 and the fifth signal reception pad electrode PE_R5 may be different from the second connection line 122 which connects the first crack detection line PCDL1 and the first signal reception pad electrode PE_R1, the second connection line 122 which connects the second crack detection line PCDL2 and the second signal reception pad electrode PE_R2, the second connection line 122 which connects the third crack detection line PCDL3 and the third signal reception pad electrode PE_R3, and the second connection line 122 which connects the fourth crack detection line PCDL4 and the fourth signal reception pad electrode PE_R4.

For example, the second connection line 122 may individually connect the plurality of crack detection lines PCDL corresponding to the plurality of signal reception pad electrodes PE_R.

During the manufacturing process of a display apparatus, the display apparatus may be cracked due to external shocks. For example, the non-active area disposed at the edge of the display apparatus is vulnerable to the external shocks to be easily cracked. At this time, the crack formed in the non-active area may propagate to the active area so that the impurity permeates to the active area through the crack, which degrades the reliability of the display apparatus.

Therefore, the crack of the display apparatus may be detected using various methods. For example, a crack detection line connected to the pad electrode may be disposed in the non-active area. Therefore, it is determined whether the crack detection line is cracked according to a feedback of a signal which is applied to the crack detection line from the pad electrode. For example, it is determined whether a crack occurs depending on whether the crack detection signal which is input to the signal transmission pad electrode from the flexible circuit board or the printed circuit board is transmitted to the signal reception pad electrode through the crack detection line and then is output to the flexible circuit board or the printed circuit board through the signal reception pad electrode. However, in this case, even though the crack detection line is configured by a plurality of wiring lines, if the plurality of wiring lines is connected in parallel to be connected to the same signal transmission pad electrode and the same signal reception pad electrode, a signal which is output to the signal reception pad electrode may be the same regardless of which wiring line is cracked. Accordingly, in this case, there is a problem in that it is detected only whether the display apparatus is cracked, but which wiring line is cracked (or which layer is cracked) may not be accurately detected.

Therefore, in the display apparatus 1000 according to the exemplary embodiment of the present disclosure, one ends of the plurality of crack detection lines PCDL may be connected to the same signal transmission pad electrode PE_T. The other ends of the plurality of crack detection lines PCDL may be connected to different signal reception pad electrodes PE_R. At this time, for example, the timing controller of the flexible circuit board FCB may read whether each of the signal reception pad electrodes E_R receives a crack detection signal. Therefore, it is possible to determine whether each of the plurality of crack detection lines PCDL is cracked. Specifically, the plurality of crack detection lines may include a first crack detection line PCDL1, a second crack detection line PCDL2, a third crack detection line PCDL3, a fourth crack detection line PCDL4, and a fifth crack detection line PCDL5. At this time, the first crack detection line PCDL1 may transmit a crack detection signal applied from the signal transmission pad electrode PE_T to the first signal reception pad electrode PE_R1. Therefore, whether the first crack detection line PCDL1 is cracked may be detected by reading whether the first signal reception pad electrode PE_R1 receives the crack detection signal. The second crack detection line PCDL2 may transmit a crack detection signal applied from the signal transmission pad electrode PE_T to the second signal reception pad electrode PE_R2. Therefore, whether the second crack detection line PCDL2 is cracked may be detected by reading whether the second signal reception pad electrode PE_R2 receives the crack detection signal. The third crack detection line PCDL3 may transmit a crack detection signal applied from the signal transmission pad electrode PE_T to the third signal reception pad electrode PE_R3. Therefore, whether the third crack detection line PCDL3 is cracked may be detected by reading whether the third signal reception pad electrode PE_R3 receives the crack detection signal. The fourth crack detection line PCDL4 may transmit a crack detection signal applied from the signal transmission pad electrode PE_T to the fourth signal reception pad electrode PE_R4. Therefore, whether the fourth crack detection line PCDL4 is cracked may be detected by reading whether the fourth signal reception pad electrode PE_R4 receives the crack detection signal. The fifth crack detection line PCDL5 may transmit a crack detection signal applied from the signal transmission pad electrode PE_T to the fifth signal reception pad electrode PE_R5. Therefore, whether the fifth crack detection line PCDL5 is cracked may be detected by reading whether the fifth signal reception pad electrode PE_R5 receives the crack detection signal. For example, in the display apparatus 1000 according to the exemplary embodiment of the present disclosure, a plurality of crack detection lines PCDL is configured and is connected to different signal reception pad electrodes PE_R. Accordingly, it is possible to individually determine whether each of the plurality of crack detection lines PCDL is cracked. Accordingly, not only whether the display apparatus 1000 is cracked, but also a wiring line which is cracked is determined so that the crack detectability may be improved. Therefore, in the display apparatus 1000 according to the exemplary embodiment of the present disclosure, the crack is precisely detected to minimize or reduce a potential defect due to the crack and improve the lifespan of the display apparatus 1000, thereby improving the reliability.

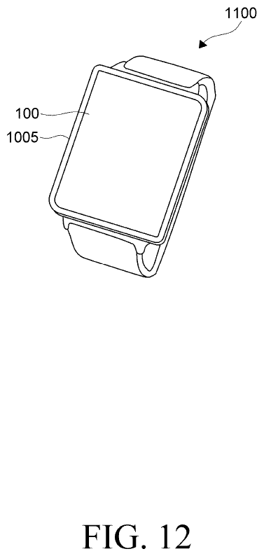

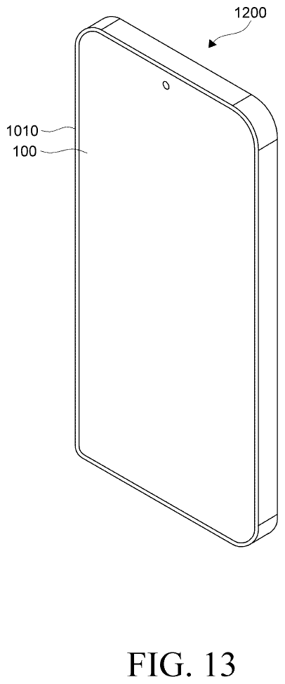

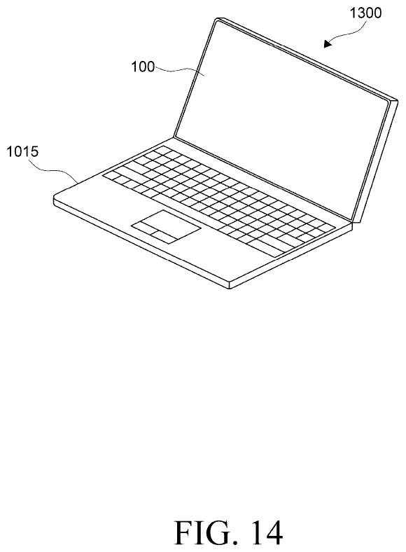

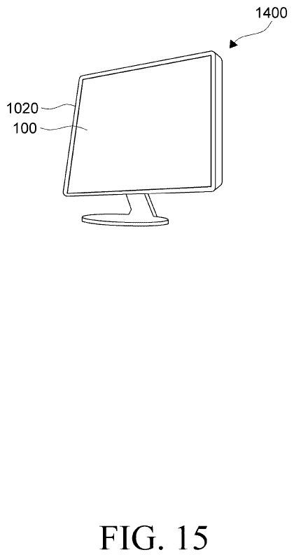

FIGS. 12 to 15 are views illustrating devices to which a display apparatus according to exemplary embodiments of the present disclosure is applied.

Referring to FIGS. 12 to 15, the display apparatus 1000 according to the exemplary embodiments of the present disclosure may be included in various apparatuses or electronic apparatuses. For example, referring to FIGS. 12 to 15, various electronic apparatuses may include a wearable device 1100, a mobile device 1200, a laptop 1300, and a monitor, or TV 1400, but the exemplary embodiments of the present disclosure are not limited thereto.

Each of the wearable device 1100, the mobile device 1200, the laptop 1300, and the monitor or the TV 1400 may include case parts 1005, 1010, 1015, and 1020 and the display panel 100 and the display apparatus 1000 according to the exemplary embodiments of the present disclosure described in FIGS. 1 to 11E.

For example, the display apparatus according to an exemplary embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop PC, a laptop PC, a netbook computer, a workstation, a navigation system, a vehicle display apparatus, a theater display apparatus, a television, a wallpaper apparatus, a signage apparatus, a game console, a laptop, a monitor, a camera, a camcorder, home appliances, etc.

The exemplary embodiments of the present disclosure can also be described as follows:

According to an aspect of the present disclosure, there is provided a display apparatus. The display apparatus includes a substrate including an active area and a non-active area adjacent to the active area, a plurality of insulating layers disposed on the substrate, a plurality of banks disposed on the plurality of insulating layers in the active area, a plurality of micro light emitting elements disposed on the banks, a plurality of wiring lines which is disposed so as to surround the active area on different insulating layers, among the plurality of insulating layers, in the non-active area and at least partially overlaps each other and a plurality of pad electrodes which is disposed on the plurality of insulating layers in the non-active area and is electrically connected to the plurality of wiring lines. One ends of each of the plurality of wiring lines are electrically connected to the same pad electrode, among the plurality of pad electrodes and the other ends of each of the plurality of wiring lines are electrically connected to different pad electrodes, among the plurality of pad electrodes.

The one ends of the plurality of wiring lines may be connected to each other through contact holes disposed in the plurality of insulating layers.

The plurality of pad electrodes may include a signal input pad electrode which is electrically connected to the one ends of the plurality of wiring lines and a plurality of signal output pad electrodes which is electrically connected to the other ends of the plurality of wiring lines, respectively.

The plurality of wiring lines may include a first wiring line, a second wiring line disposed on the first wiring line, a third wiring line disposed on the second wiring line, a fourth wiring line disposed on the third wiring line and a fifth wiring line disposed on the fourth wiring line. The plurality of signal output pad electrodes may include a first signal output pad electrode which is electrically connected to the other end of the first wiring line, a second signal output pad electrode which is electrically connected to the other end of the second wiring line, a third signal output pad electrode which is electrically connected to the other end of the third wiring line, a fourth signal output pad electrode which is electrically connected to the other end of the fourth wiring line and a fifth signal output pad electrode which is electrically connected to the other end of the fifth wiring line.

The display apparatus may further include a pixel driving circuit disposed between the substrate and the plurality of insulating layers, a plurality of 1-1-th connection lines which is disposed on a lowest one of the plurality of insulating layers in the active area and is electrically connected to the pixel driving circuit, a plurality of 1-2-th connection lines on the plurality of 1-1-th connection lines, a plurality of 1-3-th connection lines on the plurality of 1-2-th connection lines and a plurality of 1-4-th connection lines on the plurality of 1-3-th connection lines. The first wiring line may be disposed on the same layer as the plurality of 1-1-th connection lines to be formed of the same material, the second wiring line may be disposed on the same layer as the plurality of 1-2-th connection lines to be formed of the same material, the third wiring line may be disposed on the same layer as the plurality of 1-3-th connection lines to be formed of the same material, the fourth wiring line may be disposed on the same layer as the plurality of 1-4-th connection lines to be formed of the same material, and the fifth wiring line may be disposed on the same layer as the plurality of pad electrodes to be formed of the same material.

The display apparatus may further include a plurality of second connection lines which connects the plurality of pad electrodes and the plurality of wiring lines in the non-active area. Some of the plurality of second connection lines may electrically connect the signal input pad electrode and all the plurality of wiring lines, and the other second connection lines among the plurality of second connection lines may electrically individually connect the signal output pad electrode and each of the plurality of wiring lines.

Each of the plurality of micro light emitting elements may include an anode electrode, a first semiconductor layer disposed on the anode electrode, an active layer disposed on the first semiconductor layer, a second semiconductor layer disposed on the active layer and a cathode electrode disposed on the second semiconductor layer.

The display apparatus may further include a pixel driving circuit disposed between the substrate and the plurality of insulating layers, a first electrode which is disposed below the plurality of micro light emitting elements to electrically connect the pixel driving circuit and the anode electrodes of the plurality of micro light emitting elements and a solder pattern which is disposed between the first electrode and the anode electrode. The first electrode and the anode electrode may be electrically connected by eutectic bonding using the solder pattern.

The first electrode may include a first conductive layer disposed on the bank, a second conductive layer disposed on the first conductive layer, a third conductive layer disposed on the second conductive layer and a fourth conductive layer disposed on the third conductive layer. The second conductive layer may include a reflective material and an upper surface of a part of the second conductive layer may be exposed by the third conductive layer and the fourth conductive layer.

Each of the plurality of wiring lines may be disposed along a periphery of the substrate.

According to another aspect of the present disclosure, there is provided a display apparatus. The display apparatus includes a substrate which includes an active area, a first non-active area adjacent to the active area, a bending area extending from the first non-active area, and a second non-active area extending from the bending area, a plurality of insulating layers disposed on the substrate, a plurality of banks disposed on the plurality of insulating layers in the active area, a plurality of micro light emitting elements disposed on the banks, a plurality of crack detection lines which is disposed so as to surround the active area on different insulating layers, among the plurality of insulating layers, in the first non-active area and at least partially overlaps each other and a plurality of pad electrodes which is disposed on the plurality of insulating layers in the second non-active area and includes a signal transmission pad electrode and a plurality of signal reception pad electrodes which are electrically connected to the plurality of wiring lines.

Each of the plurality of crack detection lines is electrically connected to the same signal transmission pad electrode and each of the plurality of crack detection lines is electrically connected to different signal reception pad electrodes, among the plurality of signal reception pad electrodes.

The plurality of crack detection lines may include a first crack detection line, a second crack detection line disposed on the first crack detection line, a third crack detection line disposed on the second crack detection line, a fourth crack detection line disposed on the third crack detection line and a fifth crack detection line disposed on the fourth crack detection line. The plurality of signal reception pad electrodes may include a first signal reception pad electrode which is electrically connected to the first crack detection line, a second signal reception pad electrode which is electrically connected to the second crack detection line, a third signal reception pad electrode which is electrically connected to the third crack detection line, a fourth signal reception pad electrode which is electrically connected to the fourth crack detection line and a fifth signal reception pad electrode which is electrically connected to the fifth crack detection line.

The display apparatus may further include a plurality of connection lines including a plurality of first connection lines which is at least partially disposed in the first non-active area and the bending area and connects the plurality of pad electrodes and the plurality of crack detection lines in the second non-active area, a plurality of second connection lines disposed on the plurality of first connection lines, a plurality of third connection lines disposed on the plurality of second connection lines, and a plurality of fourth connection lines disposed on the plurality of third connection lines. The first crack detection line may be disposed on the same layer as the plurality of first connection lines to be formed of the same material, the second crack detection line may be disposed on the same layer as the plurality of second connection lines to be formed of the same material, the third crack detection line may be disposed on the same layer as the plurality of third connection lines to be formed of the same material, the fourth crack detection line may be disposed on the same layer as the plurality of fourth connection lines to be formed of the same material, and the fifth crack detection line may be disposed on the same layer as the plurality of pad electrodes to be formed of the same material.

The plurality of connection lines may be connected to the first crack detection line, the second crack detection line, the third crack detection line, the fourth crack detection line, and the fifth crack detection line in the first non-active area, respectively.

The plurality of crack detection lines may be disposed in an area of the first non-active area excluding a part of the first non-active area extending to the second non-active area to surround the active area.

Lengths of the plurality of crack detection lines may be different from each other.

The plurality of light emitting elements may be micro LEDs.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate including an active area and a non-active area adjacent to the active area;
a plurality of insulating layers disposed on the substrate;
a plurality of banks disposed on the plurality of insulating layers in the active area;
a plurality of light emitting elements disposed on the banks;
a plurality of wiring lines which is disposed so as to surround the active area on different insulating layers, among the plurality of insulating layers, in the non-active area and at least partially overlaps each other; and
a plurality of pad electrodes which is disposed on the plurality of insulating layers in the non-active area and is electrically connected to the plurality of wiring lines,
wherein one end of each of the plurality of wiring lines are electrically connected to the same pad electrode, among the plurality of pad electrodes and the other end of each of the plurality of wiring lines are electrically connected to different pad electrodes, among the plurality of pad electrodes.

2. The display apparatus according to claim 1, wherein the one ends of the plurality of wiring lines are electrically connected to each other through contact holes disposed in the plurality of insulating layers.

3. The display apparatus according to claim 1, wherein the plurality of pad electrodes includes:
a signal input pad electrode which is electrically connected to the one ends of the plurality of wiring lines; and
a plurality of signal output pad electrodes which is electrically connected to the other ends of the plurality of wiring lines, respectively.

4. The display apparatus according to claim 3, wherein the plurality of wiring lines includes:
a first wiring line;
a second wiring line disposed on the first wiring line;
a third wiring line disposed on the second wiring line;
a fourth wiring line disposed on the third wiring line; and
a fifth wiring line disposed on the fourth wiring line, and
the plurality of signal output pad electrodes includes:
a first signal output pad electrode which is electrically connected to the other end of the first wiring line;
a second signal output pad electrode which is electrically connected to the other end of the second wiring line;
a third signal output pad electrode which is electrically connected to the other end of the third wiring line;
a fourth signal output pad electrode which is electrically connected to the other end of the fourth wiring line; and
a fifth signal output pad electrode which is electrically connected to the other end of the fifth wiring line.

5. The display apparatus according to claim 4, further comprising:
a pixel driving circuit disposed between the substrate and the plurality of insulating layers;
a plurality of 1-1-th connection lines which is disposed on a lowest one of the plurality of insulating layers in the active area and is electrically connected to the pixel driving circuit;
a plurality of 1-2-th connection lines disposed on the plurality of 1-1-th connection lines;
a plurality of 1-3-th connection lines disposed on the plurality of 1-2-th connection lines; and
a plurality of 1-4-th connection lines disposed on the plurality of 1-3-th connection lines,
wherein the first wiring line is disposed on the same layer as the plurality of 1-1-th connection lines to be formed of the same material, the second wiring line is disposed on the same layer as the plurality of 1-2-th connection lines to be formed of the same material, the third wiring line is disposed on the same layer as the plurality of 1-3-th connection lines to be formed of the same material, the fourth wiring line is disposed on the same layer as the plurality of 1-4-th connection lines to be formed of the same material, and the fifth wiring line is disposed on the same layer as the plurality of pad electrodes to be formed of the same material.

6. The display apparatus according to claim 3, further comprising:
a plurality of second connection lines which connects the plurality of pad electrodes and the plurality of wiring lines in the non-active area,
wherein some of the plurality of second connection lines electrically connect the signal input pad electrode and all the plurality of wiring lines, and the other second connection lines among the plurality of second connection lines electrically individually connect the signal output pad electrode and each of the plurality of wiring lines.

7. The display apparatus according to claim 1, wherein each of the plurality of light emitting elements includes:
an anode electrode;
a first semiconductor layer disposed on the anode electrode;
an active layer disposed on the first semiconductor layer;
a second semiconductor layer disposed on the active layer; and
a cathode electrode disposed on the second semiconductor layer.

8. The display apparatus according to claim 7, further comprising:
a pixel driving circuit disposed between the substrate and the plurality of insulating layers;
a first electrode which is disposed below the plurality of light emitting elements to electrically connect the pixel driving circuit and the anode electrodes of the plurality of light emitting elements; and
a solder pattern which is disposed between the first electrode and the anode electrode,
wherein the first electrode and the anode electrode are electrically connected by eutectic bonding using the solder pattern.

9. The display apparatus according to claim 8, wherein the first electrode includes a first conductive layer disposed on the bank, a second conductive layer disposed on the first conductive layer, a third conductive layer disposed on the second conductive layer and a fourth conductive layer disposed on the third conductive layer, and
wherein the second conductive layer includes a reflective material and an upper surface of a part of the second conductive layer is exposed by the third conductive layer and the fourth conductive layer.

10. The display apparatus of claim 1, wherein each of the plurality of wiring lines is disposed along a periphery of the substrate.

11. A display apparatus comprising:
a substrate which includes an active area, a first non-active area adjacent to the active area, a bending area extending from the first non-active area, and a second non-active area extending from the bending area;
a plurality of insulating layers disposed on the substrate;
a plurality of banks disposed on the plurality of insulating layers in the active area;
a plurality of light emitting elements disposed on the banks;
a plurality of crack detection lines which is disposed so as to surround the active area on different insulating layers, among the plurality of insulating layers, in the first non-active area and at least partially overlaps each other; and
a plurality of pad electrodes which is disposed on the plurality of insulating layers in the second non-active area and includes a signal transmission pad electrode and a plurality of signal reception pad electrodes which are electrically connected to a plurality of wiring lines.

12. The display apparatus according to claim 11,
wherein each of the plurality of crack detection lines is electrically connected to the same signal transmission pad electrode and each of the plurality of crack detection lines is electrically connected to different signal reception pad electrodes, among the plurality of signal reception pad electrodes.

13. The display apparatus according to claim 11, wherein the plurality of crack detection lines includes:
a first crack detection line;
a second crack detection line disposed on the first crack detection line;
a third crack detection line disposed on the second crack detection line;
a fourth crack detection line disposed on the third crack detection line; and
a fifth crack detection line disposed on the fourth crack detection line, and
the plurality of signal reception pad electrodes includes:
a first signal reception pad electrode which is electrically connected to the first crack detection line;
a second signal reception pad electrode which is electrically connected to the second crack detection line;
a third signal reception pad electrode which is electrically connected to the third crack detection line;
a fourth signal reception pad electrode which is electrically connected to the fourth crack detection line; and
a fifth signal reception pad electrode which is electrically connected to the fifth crack detection line.

14. The display apparatus according to claim 13, further comprising:
a plurality of connection lines including a plurality of first connection lines which is at least partially disposed in the first non-active area and the bending area and connects the plurality of pad electrodes and the plurality of crack detection lines in the second non-active area, a plurality of second connection lines disposed on the plurality of first connection lines, a plurality of third connection lines disposed on the plurality of second connection lines, and a plurality of fourth connection lines disposed on the plurality of third connection lines,
wherein the first crack detection line is disposed on the same layer as the plurality of first connection lines to be formed of the same material, the second crack detection line is disposed on the same layer as the plurality of second connection lines to be formed of the same material, the third crack detection line is disposed on the same layer as the plurality of third connection lines to be formed of the same material, the fourth crack detection line is disposed on the same layer as the plurality of fourth connection lines to be formed of the same material, and the fifth crack detection line is disposed on the same layer as the plurality of pad electrodes to be formed of the same material.

15. The display apparatus according to claim 14, wherein the plurality of connection lines is electrically connected to the first crack detection line, the second crack detection line, the third crack detection line, the fourth crack detection line, and the fifth crack detection line in the first non-active area, respectively.

16. The display apparatus according to claim 11, wherein the plurality of crack detection lines is disposed in an area of the first non-active area excluding a part of the first non-active area extending to the second non-active area to surround the active area.

17. The display apparatus according to claim 11, wherein lengths of the plurality of crack detection lines are different from each other.

18. The display apparatus according to claim 1, wherein the plurality of wiring lines are configured to detect a disconnection based on signal interruption along any one of the wiring lines.

19. The display apparatus according to claim 11, wherein the plurality of crack detection lines are formed using conductive materials having different ductility characteristics.

20. The display apparatus according to claim 11, wherein the plurality of pad electrodes includes a signal input pad electrode configured to receive a crack detection signal, the crack detection signal being transmitted through each of the plurality of wiring lines.
